(19) United States
(12) Patent Application Publication
(10) Pub. No.: US 2024/0039236 A1
(43) Pub. Date: Feb. 1, 2024

(54) LINE NARROWING MODULE, GAS LASER DEVICE, AND ELECTRONIC DEVICE MANUFACTURING METHOD

(71) Applicant: Gigaphoton Inc., Tochigi (JP)

(72) Inventor: Hitoshi OHGA, Oyama-shi (JP)

(73) Assignee: Gigaphoton Inc., Tochigi (JP)

(21) Appl. No.: 18/483,903

(22) Filed: Oct. 10, 2023

Related U.S. Application Data
(63) Continuation of application No. PCT/JP2021/019662, filed on May 24, 2021.

(51) Int. Cl. H01S 3/136; H01S 3/13; G03F 7/00

(52) U.S. Cl. CPC H01S 3/136; H01S 3/1305; G03F 7/70025; G02B 27/4233

(57) ABSTRACT

A line narrowing module includes: a prism; a mirror including a reflective surface, first and second adjacent surfaces, and an opposing surface; a grating wavelength-dispersing light reflected by the reflective surface; a holding part holding the mirror; a first adhesive provided between the holding part and the first adjacent surface or between the holding part and the opposing surface and bonding the mirror to the holding part; a second adhesive provided between the holding part and the second adjacent surface and bonding the mirror to the holding part; and a driving unit rotating the holding part to rotate the mirror about an axis perpendicular to a plane where the light is wavelength-dispersed. The second adhesive is located on an opposite side of the first adhesive with respect to a center line of the mirror in parallel to the axis.

### CROSS-REFERENCE TO RELATED APPLICATIONS

The present application is a continuation application of International Application No. PCT/JP2021/019662, filed on May 24, 2021, the entire contents of which are hereby incorporated by reference.

### BACKGROUND

### 1. Technical Field

The present disclosure relates to a line narrowing module, a gas laser device, and an electronic device manufacturing method.

### 2. Related Art

Recently, in a semiconductor exposure device, improvement in resolution has been desired for miniaturization and high integration of semiconductor integrated circuits. For this purpose, an exposure light source that outputs light having a shorter wavelength has been developed. For example, as the gas laser device for exposure, a KrF excimer laser device that outputs a laser beam having a wavelength of about 248.0 nm and an ArF excimer laser device that outputs a laser beam having a wavelength of about 193.4 nm are used.

Spectral linewidths of natural oscillation beams of the KrF excimer laser device and the ArF excimer laser device are as wide as from 350 pm to 400 pm. Therefore, when a projection lens is composed of a material that transmits ultraviolet light such as KrF laser beam and ArF laser beam, chromatic aberration may occur. As a result, the resolution may decrease. Given this, a spectral line width of laser beam output from the gas laser device needs to be narrowed to the extent that the chromatic aberration is ignorable. Therefore, in the laser resonator of the gas laser device, a line narrowing module (Line Narrow Module: LNM) including a line narrowing element (etalon or grating, etc.) may be provided in order to narrow the spectral linewidth. Hereinafter, a gas laser device with a narrowed spectral line width is referred to as a line narrowing gas laser device.

### LIST OF DOCUMENTS

### Patent Documents

Patent Document 1: Japanese Unexamined Patent Application Publication No. 2017-9933
Patent Document 2: U.S. Pat. No. 6,867,848
Patent Document 3: U.S. Pat. No. 7,113,263
Patent Document 4: Japanese Unexamined Patent Application Publication No. 2019-3046

### SUMMARY

A line narrowing module according to an aspect of the present disclosure may include a prism; a mirror including a reflective surface, a first adjacent surface and a second adjacent surface adjacent to the reflective surface, and an opposing surface opposed to the reflective surface, the reflective surface reflecting light transmitted through the prism; a grating that wavelength-disperses the light reflected by the reflective surface; a holding part that holds the mirror; a first adhesive provided between the holding part and the first adjacent surface or between the holding part and the opposing surface and bonding the mirror to the holding part; a second adhesive provided between the holding part and the second adjacent surface and bonding the mirror to the holding part; and a driving unit configured to rotate the holding part so that the mirror rotates about an axis perpendicular to a plane in which the light is wavelength-dispersed. The second adhesive may be located on an opposite side of the first adhesive with respect to a center line which passes through a center of the mirror in parallel to the axis when the reflective surface is viewed from the front.

A gas laser device according to an aspect of the present disclosure may be provided with a line narrowing module, the line narrowing module including a prism; a mirror including a reflective surface, a first adjacent surface and a second adjacent surface adjacent to the reflective surface, and an opposing surface opposed to the reflective surface, the reflective surface reflecting light transmitted through the prism; a grating that wavelength-disperses the light reflected by the reflective surface; a holding part that holds the mirror; a first adhesive provided between the holding part and the first adjacent surface or between the holding part and the opposing surface and bonding the mirror to the holding part; a second adhesive provided between the holding part and the second adjacent surface and bonding the mirror to the holding part; and a driving unit configured to rotate the holding part so that the mirror rotates about an axis perpendicular to a plane in which the light is wavelength-dispersed. The second adhesive may be located on an opposite side of the first adhesive with respect to a center line which passes through a center of the mirror in parallel to the axis when the reflective surface is viewed from the front.

A method of manufacturing an electronic device according to an aspect of the present disclosure may include: generating a laser beam by a gas laser device provided with a line narrowing module, the line narrowing module including a prism, a mirror including a reflective surface, a first adjacent surface and a second adjacent surface adjacent to the reflective surface, and an opposing surface opposed to the reflective surface, the reflective surface reflecting light transmitted through the prism, a grating that wavelength-disperses the light reflected by the reflective surface, a holding part that holds the mirror, a first adhesive provided between the holding part and the first adjacent surface or between the holding part and the opposing surface and bonding the mirror to the holding part, a second adhesive provided between the holding part and the second adjacent surface and bonding the mirror to the holding part, and a driving unit configured to rotate the holding part so that the mirror rotates about an axis perpendicular to a plane in which the light is wavelength-dispersed, the second adhesive being located on an opposite side of the first adhesive with respect to a center line which passes through a center of the mirror in parallel to the axis when the reflective surface is viewed from front; outputting the laser beam to an exposure device; and exposing a photosensitive substrate to the laser beam in the exposure device to produce the electronic device.

### BRIEF DESCRIPTION OF THE DRAWINGS

Embodiments of the present disclosure will be described below merely as examples with reference to the accompanying drawings.

FIG. 1 is a schematic diagram illustrating an overall configuration example of an entire electronic device manufacturing apparatus.

FIG. 2 is a schematic diagram illustrating an overall configuration example of a gas laser device of a comparative example.

FIG. 3 is a schematic diagram illustrating a first overall configuration example of a mirror unit in the comparative example.

FIG. 4 is a front view of the mirror unit shown in FIG. 3.

FIG. 5 is a schematic diagram illustrating a second overall configuration example of the mirror unit in the comparative example.

FIG. 6 is a front view of the mirror unit shown in FIG. 5.

FIG. 7 is a schematic diagram illustrating an overall configuration example of a mirror unit according to a first embodiment.

FIG. 8 is a front view of the mirror unit shown in FIG. 7.

FIG. 9 is a side view of the mirror unit viewed from a plate member side.

FIG. 10 is a front view of a mirror unit in a first modification of the first embodiment.

FIG. 11 is a schematic diagram illustrating an overall configuration example of a mirror unit according to a second modification of the first embodiment.

FIG. 12 is a front view of the mirror unit shown in FIG. 11.

FIG. 13 is a front view of the mirror unit according to a second embodiment.

FIG. 14 is a front view of a mirror unit in a first modification of the second embodiment.

FIG. 15 is a front view of a mirror unit in a second modification of the second embodiment.

FIG. 16 is a front view of a mirror unit according to a third embodiment.

FIG. 17 is a front view of a mirror unit according to a modification of the third embodiment.

FIG. 18 is an enlarged view of the periphery of an adhesive in a fourth embodiment.

FIG. 19 is an enlarged view of the periphery of an adhesive in a modification of the fourth embodiment.

FIG. 20 is a front view of the mirror unit according to the fifth embodiment.

FIG. 21 is a diagram for illustrating the arrangement of the driving unit in the sixth embodiment.

FIG. 22 is a schematic diagram illustrating an overall configuration example of a mirror unit in a modification of the sixth embodiment.

FIG. 23 is a diagram for describing an arrangement of a driving unit in a modification of the sixth embodiment.

### DESCRIPTION OF EMBODIMENTS

### 1. Description of Electronic Device Manufacturing Apparatus Used in Exposure Process of Electronic Device

### 2. Description of Gas Laser Device of Comparative Example

2.1 Configuration

2.2 Operation

2.3 Problem

### 3. Description of Line Narrowing Module of First Embodiment

3.1 Configuration

3.2 Function and Effect

### 4. Description of Line Narrowing Module of Second Embodiment

4.1 Configuration

4.2 Function and Effect

### 5. Description of Line Narrowing Module of Third Embodiment

5.1 Configuration

5.2 Function and Effect

### 6. Description of Line Narrowing Module of Fourth Embodiment

6.1 Configuration

6.2 Function and Effect

### 7. Description of Line Narrowing Module of Fifth Embodiment

7.1 Configuration

7.2 Function and Effect

### 8. Description of Line Narrowing Module of Sixth Embodiment

8.1 Configuration

8.2 Function and Effect

Hereinafter, embodiments of the present disclosure will be described in detail with reference to the drawings.

The embodiments described below show some examples of the present disclosure and do not limit the contents of the present disclosure. In addition, all configurations and operation described in the embodiments are not necessarily essential as configurations and operation of the present disclosure. Here, the same components are denoted by the same reference numerals, and redundant description thereof is omitted.

### 1. Description of Electronic Device Manufacturing Apparatus Used in Exposure Process of Electronic Device

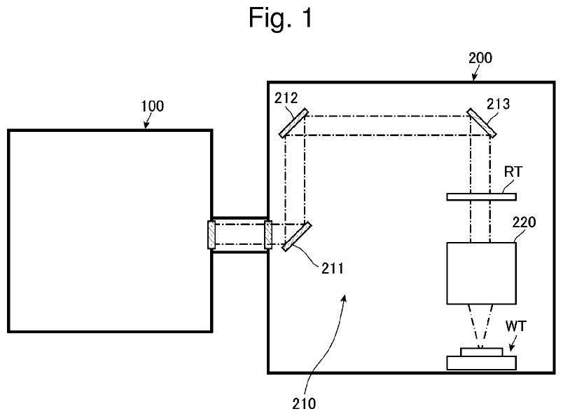

FIG. 1 is a schematic diagram illustrating an overall configuration example of an electronic device manufacturing apparatus used in an exposure process of an electronic device. As shown in FIG. 1, the manufacturing apparatus used in the exposure process includes a gas laser device 100 and an exposure device 200. The exposure device 200 includes an illumination optical system 210 including a plurality of mirrors 211, 212, and 213 and a projection optical system 220. The illumination optical system 210 illuminates a reticle pattern of a reticle stage RT by the laser beam entering from the gas laser device 100. The projection optical system 220 performs reduction projection of the laser beam transmitted through the reticle and forms an image on a workpiece (not illustrated) disposed on a workpiece table WT. The workpiece is a photosensitive substrate such as a semiconductor wafer on which photoresist is applied. The exposure device 200 synchronously translates the reticle stage RT and the workpiece table WT to expose the workpiece to a laser beam reflecting the reticle pattern. Through the exposure process as described above, a device pattern is transferred onto the semiconductor wafer, whereby a semiconductor device, which is an electronic device, can be manufactured.

### 2. Description of Gas Laser Device of Comparative Example

2.1 Configuration

The gas laser device 100 of the comparative example will be described. The comparative example of the present disclosure is an example recognized by the applicant as known only by the applicant, and is not a publicly known example admitted by the applicant.

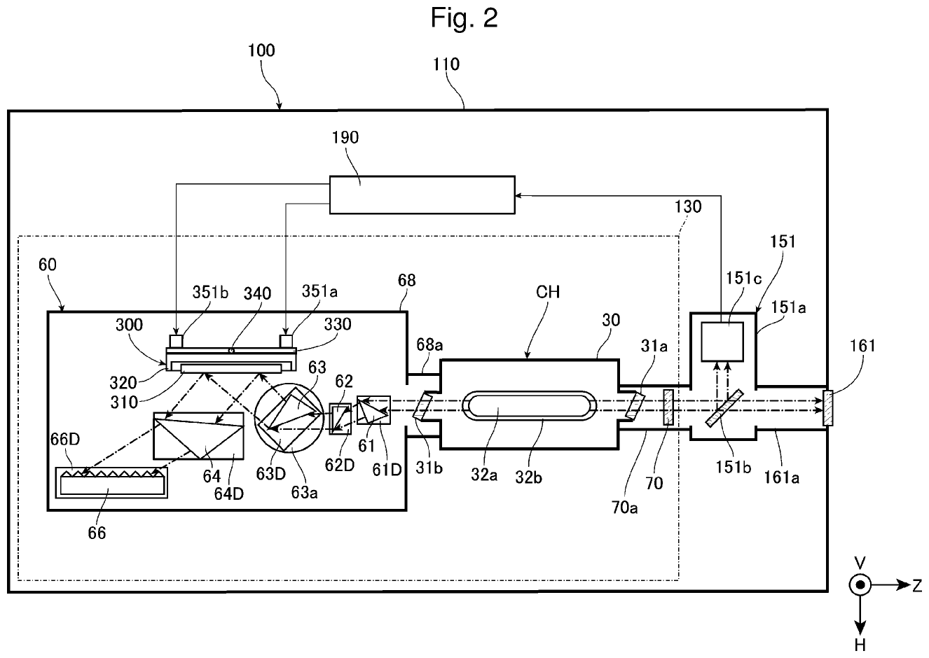

FIG. 2 is a schematic diagram illustrating an overall configuration example of the gas laser device 100 of the present example. The gas laser device 100 is, for example, an ArF excimer laser device using a mixed gas including argon (Ar), fluorine (F₂), and neon (Ne). In this case, the gas laser device 100 outputs a pulsed laser beam having a center wavelength of about 193.4 nm. The gas laser device 100 may be a gas laser device other than the ArF excimer laser device, and may be, for example, a KrF excimer laser device using a mixed gas including krypton (Kr), F₂, and Ne. The gas laser device 100 outputs a pulsed laser beam having a center wavelength of about 248.0 nm. A mixed gas containing Ar, F₂ and Ne which are laser media, or a mixed gas containing Kr, F₂, and Ne, which are laser media, may be referred to as a laser gas. In the mixed gas used in each of the ArF excimer laser device and the KrF excimer laser device, high-purity nitrogen (N₂) or helium (He) may be used instead of Ne.

The gas laser device 100 of the present example mainly includes a housing 110, a laser oscillator 130 disposed in an internal space of the housing 110, a detection unit 151, and a processor 190.

The laser oscillator 130 mainly includes a chamber device CH, a charger (not illustrated), a pulse power module (not illustrated), a line narrowing module 60, and an output coupling mirror 70.

In FIG. 2, the interior configuration of the chamber device CH is illustrated as viewed from a direction substantially perpendicular to the traveling direction of the laser beam. The chamber device CH mainly includes a housing 30, a pair of windows 31a and 31b, and a pair of electrodes 32a and 32b. Hereinafter, a direction parallel to the optical axis direction of the pulsed laser beam output from the chamber device CH will be described as a Z direction, a direction orthogonal to the Z direction will be described as an H direction, and a direction orthogonal to the Z direction and the H direction will be described as a V direction.

The housing 30 is supplied with the laser gas from a laser gas supply device (not illustrated) to an internal space of the housing 30 via a pipe (not illustrated), and encloses the laser gas in the internal space. The light generated by the excitation of the laser gas travels in the windows 31a and 31b.

The window 31a and the window 31b are provided at positions facing each other in the housing 30. The window 31a is located on a front side in the traveling direction of the laser beam from the gas laser device 100 to the exposure device 200, and the window 31b is located on a rear side in the traveling direction. The windows 31a and 31b are inclined so as to form a Brewster's angle with respect to the traveling direction of the laser beam so that reflection of P-polarized light of the laser beam is suppressed. The window 31a is disposed in a hole on a front-side wall surface of the housing 30, and the window 31b is disposed in a hole on a rear-side wall surface of the housing 30.

The longitudinal direction of the electrodes 32a and 32b is along the traveling direction of the laser beam, and the electrodes 32a and 32b are disposed to face each other in the inner space of the housing 30. The electrode 32b is located below the electrode 32a in the V direction and is shown larger than the electrode 32a for ease of viewing, but the electrode 32b is substantially the same in size as the electrode 32a. The space between the electrode 32a and the electrode 32b is sandwiched between the window 31a and the window 31b. The electrodes 32a and 32b are discharge electrodes for exciting the laser medium by glow discharge. In the present example, the electrode 32a is the cathode and the electrode 32b is the anode.

The electrode 32a is supported by an insulating portion (not illustrated). The insulating portion closes an opening (not illustrated) that is continuous with the housing 30. The insulating portion includes an insulator. Examples of the insulator include alumina ceramics having poor reactivity with F₂ gases. In addition, a feedthrough (not illustrated) made of a conductive member is disposed in the insulating portion. The feedthrough applies a voltage supplied from the pulse power module to the electrode 32a. The electrode 32b is supported by an electrode holder (not illustrated) and is electrically connected to the electrode holder.

The charger (not illustrated) is a DC power supply device that charges a capacitor (not illustrated) provided in the pulse power module with a predetermined voltage. The charger is disposed outside the housing 30 and is connected to the pulse power module. The pulse power module includes a switch (not illustrated) controlled by the processor 190. When the switch is switched from OFF to ON under the control of the processor 190, the pulse power module boosts the voltage applied from the charger to generate a pulsed high voltage and applies this high voltage to the electrodes 32a and 32b. When a high voltage is applied, breakdown occurs between the electrode 32a and the electrode 32b and discharge occurs. The laser gas in the housing 30 is excited by the energy of the discharge and shifts to a high energy level. When the excited laser gas then transitions to a low energy level, it outputs light corresponding to the energy level difference. The outgoing light passes through the windows 31a and 31b and is output to the outside of the housing 30.

The line narrowing module 60 mainly includes a housing 68, prisms 61, 62, 63, and 64 disposed in an internal space of the housing 68, a mirror unit 300, and a grating 66. The housing 68 is connected to the rear side of the housing 30 via the optical path pipe 68a. Specifically, one end of the optical path pipe 68a is connected to the rear side of the housing 30 so as to surround the window 31b. Further, the other end of the optical path pipe 68a is connected to the housing 68 so as to surround the opening which is continuous with the housing 68.

The prisms 61, 62, 63, and 64 expand the beam-width of the light output from the window 31b and cause the light to enter the grating 66. Further, the prisms 61, 62, 63, and 64 reduce the beam width of the light reflected from the grating 66 and return the light to the inner space of the housing 30 through the window 31b.

Each of the prisms 61, 62, 63, and 64 is constituted by, for example, calcium fluoride, quartz, or a combination of calcium fluoride and quartz. Each of the prisms 61, 62, 63, and 64 has a right-angled triangular prism shape having a right-angled triangular bottom surface. A film is formed on a side surface of the three side surfaces of the prism 61 including the oblique side of the bottom surface so as to suppress the reflection of the P-polarized light of the laser beam traveling to the side surface. The remaining two of the three side surfaces are perpendicular to each other. Films are formed on the two side surfaces so that reflection of the laser beam traveling on the two side surfaces is suppressed. The films may be films including at least one of SiO₂, MgF₂, LaF₃, and GdF₃. In particular, a fluoride-based material resistant to ultraviolet light may be used as the material of the film. It is preferred that a material of the same type as that of the prism 61 is used as the material of the film. Although the bottom surface and the side surface of the prism 61 have been described above, the same applies to the other prisms 62, 63, and 64.

The prisms 61, 62, 63, and 64 are respectively fixed to mounting portions 61D, 62D, 63D, and 64D which are stages. The mounting portions 61D, 62D, and 64D are fixed to the bottom surface of the housing 68 in the inner space of the housing 68. Thus, the prisms 61, 62, and 64 do not move relative to the housing 68 and the grating 66. On the other hand, the mounting portion 63D is fixed to a rotating stage 63a, and the rotating stage 63a is fixed to the bottom surface of the housing 68 in the inner space of the housing 68. The rotating stage 63a rotates the mounting portion 63D and the prism 63 around the V-axis perpendicular to an HZ plane in which the light output from the prism 63 is wavelength-dispersed. The rotating stage 63a is connected to a prism driving unit (not illustrated) disposed outside the housing 68. The prism driving unit is a motor, and the rotating stage 63a is rotated under the control of the prism driving unit. The prism driving unit is electrically connected to the processor 190. The processor 190 is electrically connected to the exposure device 200 and the detection unit 151. To the processor 190, a signal relating to the wavelength of light to be output by the gas laser device 100 is input from the exposure device 200. Further, a signal indicating the pulse energy of the pulsed laser beam measured by the detection unit 151 is input to the processor 190 from the detection unit 151. The processor 190 controls the prism driving unit on the basis of these signals. Therefore, the processor 190 can adjust the rotation angle of the rotating stage 63a by controlling the prism driving unit. The mounting portion 63D may be integrated with the rotating stage 63a.

The mirror unit 300 mainly includes a mirror 310, a holding part 320, a rotating stage 330, a shaft 340, and driving units 351a and 351b.

The mirror 310 is disposed between the prism 63 and the prism 64 on the optical path of the light in the line narrowing module 60. The mirror 310 reflects the light from the prism 63 toward the prism 64 and reflects the light from the prism 64 toward the prism 63. That is, the mirror 310 folds back the light traveling in the internal space of the housing 68, so that the optical path of the light is adjusted so as to fit a limited space in the internal space of the housing 68. The mirror 310 may be disposed between other prisms or may be disposed between the prism 64 and the grating 66 so long as the optical path of the light can be adjusted.

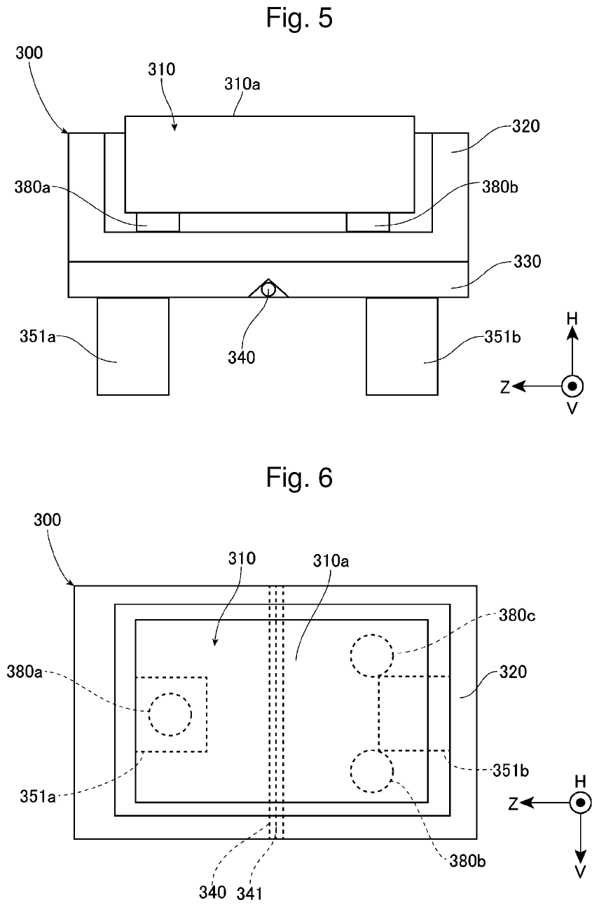

The mirror 310 is held by the holding part 320 via an adhesive, and the holding part 320 is fixed to the rotating stage 330. The shaft 340 is disposed on the rotating stage 330 along the V direction. The rotating stage 330 is connected to the driving units 351a and 351b, and rotates the holding part 320 and the mirror 310 about the shaft 340 by rotating the shaft 340 about the axis under the control of the driving units 351a and 351b. The driving units 351a and 351b are electrically connected to the processor 190. The processor 190 controls the driving units 351a and 351b on the basis of the signal from the exposure device 200 and the signal from the detection unit 151, similarly to the rotating stage 63a. Therefore, the processor 190 can adjust the rotation angle of the rotating stage 330 by controlling the driving units 351a and 351b. Details of the configuration of the mirror unit 300 will be described later with reference to FIGS. 5 and 6.

When the prism 63 and the mirror 310 are slightly rotated and the orientation is changed, the direction of the light output from the prism 63 and the mirror 310 is changed, whereby the incident angle of the light incident on the grating 66 is adjusted. By adjusting the incident angle of the light to the grating 66, the wavelength of the light reflected by the grating 66 and incident on the chamber device CH is adjusted. Accordingly, the light output from the window 31b of the housing 30 is reflected by the grating 66 through the prisms 61, 62, 63, and 64 and the mirror 310, and thus the wavelength of the light incident on the housing 30 is adjusted to a desired wavelength. Although the number of prisms is four in the present example, if at least one prism rotating like the prism 63 is included, it may be three or less, or may be five or more.

The grating 66 is a dispersive optical element. The surface of the grating 66 is made of a highly reflective material, and a large number of grooves are provided on the surface at predetermined intervals. The cross-sectional shape of each groove is, for example, a right-angled triangle. Light entering the grating 66 from the prism 64 is reflected by these grooves in a wavelength dispersive manner in the HZ plane, and is diffracted in a direction corresponding to the wavelength of the light. The grating 66 is disposed so that the incident angle of the light incident on the grating 66 from the prism 64 coincides with the diffraction angle of the diffracted light having a desired wavelength. As a result, light having a desired wavelength is returned to the housing 30 via the prisms 61, 62, 63, and 64 and the mirror 310. In the present example, the grating 66 may be an echelle grating blazed to a wavelength of about 193.4 nm. The grating 66 is fixed to the mounting portion 66D which is a stage, and the mounting portion 66D is fixed to the housing 68 in the inner space of the housing 68. Thus, the grating 66 does not move relative to the housing 68.

The output coupling mirror 70 faces the window 31a. The output coupling mirror 70 is coated with a partially reflective film. The output coupling mirror 70 transmits a part of the laser beam from the window 31a, reflects another part of the laser beam, and returns the laser beam to the inner space of the housing 30 through the window 31a. The output coupling mirror 70 includes, for example, an element in which a dielectric multilayer film is formed on a substrate of calcium fluoride. The output coupling mirror 70 is connected to the front-side of the housing 30 and is fixed to the inner space of the optical path pipe 70a surrounding the window 31a via a damper (not illustrated).

The grating 66 and the output coupling mirror 70 provided across the housing 30 constitute a resonator that resonates light output from the laser gas. The housing 30 is disposed on the optical path of the resonator, and the light output from the housing 30 reciprocates between the grating 66 and the output coupling mirror 70. The reciprocating light is amplified each time it passes through the laser gain space between the electrode 32a and the electrode 32b. A part of the amplified light passes through the output coupling mirror 70 as a pulsed laser beam and travels to the detection unit 151.

The detection unit 151 mainly includes a housing 151a, a beam splitter 151b, and an optical sensor 151c. An opening is continuously formed in the housing 151a, and an optical path pipe 70a is connected to surround the opening. Therefore, the housing 151a communicates with the optical path pipe 70a through the opening.

The beam splitter 151b is disposed on the optical path of the pulsed laser beam in the inner space of the housing 151a. The beam splitter 151b transmits a part of the pulsed laser beam traveling from the output coupling mirror 70 to the exit window 161 with a higher transmittance. The beam splitter 151b reflects another part of the pulsed laser beam toward the light receiving surface of the optical sensor 151c.

The optical sensor 151c is disposed in an inner space of the housing 151a. The optical sensor 151c measures the pulse energy of the pulsed laser beam entering the light receiving surface of the optical sensor 151c. The optical sensor 151c is electrically connected to the processor 190 and outputs a signal indicating pulse energy to be measured to the processor 190. The processor 190 controls a voltage applied to the electrodes 32a and 32b on the basis of the signal.

An opening is connected to a side of the housing 151a opposite to a side to which the optical path pipe is connected, and the optical path pipe 161a is connected so as to surround the opening. Therefore, the internal space of the housing 151a and the internal space of the optical path pipe 161a are in communication with each other. Further, the optical path pipe 161a is connected to the housing 110. An exit window 161 is provided at a position surrounded by the optical path pipe 161a in the housing 110. The light transmitted through the beam splitter 151b of the detection unit 151 is output from the exit window 161 to the exposure device 200 outside the housing 110.

The optical path pipes 68a, 70a, and 161a and the inner space of the housings 68 and 151a are filled with a purge gas via a pipe (not illustrated). The purge gas includes an inert gas such as high-purity nitrogen having less impurities such as oxygen. The purge gas is supplied from a purge gas supply source (not illustrated) disposed outside the housing 110 to the optical path pipes 68a, 70a, and 161a or the inner space of the housings 68 and 151a through a pipe (not illustrated).

The processor 190 of the present disclosure is a processing device including a storage device in which a control program is stored and a CPU which executes the control program. The processor 190 is specifically configured or programmed to perform various processes included in the present disclosure. The processor 190 controls the entire gas laser device 100. The processor 190 is electrically connected to a processor (not illustrated) of the exposure device 200, and transmits and receives various signals to and from the processor.

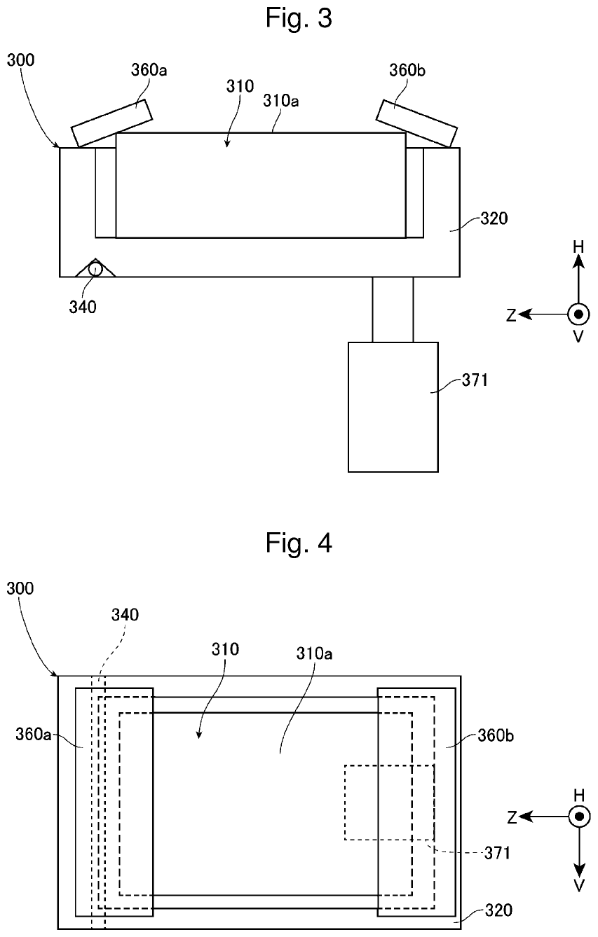

Next, a first overall configuration example of the mirror unit 300 of the comparative example will be described. FIG. 3 is a schematic diagram showing a first overall configuration example of the mirror unit 300 of the comparative example, and FIG. 4 is a front view of the mirror unit 300 shown in FIG. 3. In the mirror unit 300 shown in FIGS. 3 and 4, a part of the configuration is different from that of the mirror unit 300 shown in FIG. 2, in that the rotating stage 330 and the driving units 351a and 351b are not provided, a pair of leaf springs 360a and 360b are provided, and a driving unit 371 is provided. In FIG. 4, the part covered by the leaf springs 360a and 360b of the mirror 310 and the holding part 320 is indicated by a broken line, and the shaft 340 and the driving unit 371 arranged below the holding part 320 in the H direction are indicated by a broken line different from the broken line.

The mirror 310 has a quadrangular prism shape. The mirror 310 includes a reflective surface 310a that reflects light passing through the prism and a surface other than the reflective surface 310a. The reflective surface 310a is the surface of the mirror 310 that is along a VZ plane, and has a rectangular shape elongated in the Z direction in the VZ plane. The surface other than the reflective surface 310a includes a side surface and a rear surface of the mirror 310 facing the reflective surface 310a. The side surface is an adjacent surface adjoining the reflective surface 310a, and the rear surface is an opposing surface facing the reflective surface 310a.

The holding part 320 is a frame-shaped member having a bottom portion, and an opening is provided inside a peripheral wall that is a frame of the holding part 320, and the peripheral wall and the opening have a rectangular shape that is elongated in the Z direction in the VZ plane. In the holding part 320, the mirror 310 is placed on the surface of the bottom portion via the rear surface of the mirror 310. The peripheral wall of the holding part 320 surrounds the side surface of the mirror 310 so that a gap is provided between the side surface of the mirror 310 and the inner peripheral surface of the peripheral wall of the holding part 320. In the H direction, the upper surface of the peripheral wall is located at a position lower than the reflective surface 310a. A V-groove is provided on a rear surface of a bottom portion opposite to the front surface on which the mirror 310 is placed. A shaft 340 is disposed in the V-groove, and the V-groove and the shaft 340 are along the V direction perpendicular to the HZ plane in which the light is wavelength-dispersed. The V-groove and the shaft 340 are provided on the end side of the holding part 320 in the Z direction. The shaft 340 shown in FIGS. 3 and 4 is a rod-shaped member.

Main surfaces of the leaf springs 360a and 360b each have a rectangular shape that is elongated in the V direction in the VZ plane. Each of the leaf springs 360a and 360b is disposed at both ends of the reflective surface 310a in the Z direction, and presses the mirror 310 against the bottom wall, which is the bottom wall of the holding part 320, to fix the mirror 310 to the holding part 320.

The driving unit 371 is disposed on the rear surface of the bottom portion of the holding part 320, and the driving shaft of the driving unit 371 is fixed to the rear surface of the bottom portion of the holding part 320 along the H direction. The driving unit 371 is disposed on the end side of the holding part 320 on the opposite side of the shaft 340 in the Z direction. In addition, the driving unit 371 is disposed substantially in the center of the holding part 320 in the V direction. The driving unit 371 is, for example, a stepping motor. When a driving shaft pushes and pulls the holding part 320 in the H direction by the driving of the driving unit 371, the holding part 320 rotates about the shaft 340. As a result, the mirror 310 rotates about the shaft 340, whereby the rotation angle of the mirror 310 is adjusted.

Next, a second overall configuration example of the mirror unit 300 of the comparative example will be described. FIG. 5 is a schematic diagram illustrating a second overall configuration example of the mirror unit 300 of the comparative example. FIG. 6 is a front view of the mirror unit 300 shown in FIG. 5. In FIG. 5 and FIG. 6, configurations similar to those described above are denoted by identical reference signs, and duplicate description thereof is omitted unless otherwise specified. In FIG. 6, adhesives 380a, 380b, and 380c disposed below the mirror 310 in the H direction are indicated by broken lines. The mirror unit 300 illustrated in FIGS. 5 and 6 is the mirror unit 300 illustrated in FIG. 2, and is different from the mirror unit 300 illustrated in FIG. 3. In FIG. 2, the adhesives 380a, 380b, and 380c are omitted for ease of viewing.

Each of the adhesives 380a, 380b, and 380c is provided between the surface of the mirror 310 other than the reflective surface 310a and the holding part 320, adheres to the surface and the holding part 320, and bonds the mirror 310 to the holding part 320. In the comparative example, each of the adhesives 380a, 380b, and 380c is provided in the VZ plane between the rear surface of the mirror 310 and the surface of the bottom portion of the holding part 320, and bonds the mirror 310 to the holding part 320. The adhesives 380a, 380b, and 380c may include, for example, an epoxy resin, and the adhesives 380a, 380b, and 380c cure and shrink upon bonding. The heights of the adhesives 380a, 380b, and 380c are substantially the same in the H direction. The adhesive 380a is provided on the opposite side to the adhesives 380b and 380c with respect to the shaft 340, in particular with respect to a center line 341 parallel to the shaft 340 and passing through the center of the mirror 310. Although two adhesives may be used, three or more adhesives define and fix a surface, so that the orientation of the mirror 310 is stabilized. Further, when four or more adhesives are provided on the VZ plane, the reflective surface 310a may be distorted due to the difference in height of the respective adhesives. Therefore, the number of adhesives is preferably three.

As described above, the holding part 320 holds the mirror 310 via the adhesives 380a, 380b, and 380c. The holding part 320 is mounted on the surface of the rotating stage 330 and fixed to the rotating stage 330 by a fastening member (not illustrated). The mirror 310 is replaceable together with the holding part 320 with respect to the rotating stage 330. The rotating stage 330 may be integrated with the holding part 320.

The V-groove is provided on the rear surface of the rotating stage 330, and the shaft 340 is disposed in the V-groove. The V-groove and the shaft 340 are along the V direction. The shaft 340 shown in FIGS. 5 and 6 is a rod-shaped member, but may be a virtual shaft without a substance. In addition, the V-groove and the shaft 340 are provided substantially in the center of the mirror 310 and the rotating stage 330 in the Z direction, and pass through the center of the mirror 310 when the reflective surface 310a is viewed from the front.

Further, the driving units 351a and 351b are disposed on the rear surface of the rotating stage 330. The driving units 351a and 351b are piezoelectric devices. The driving units 351a and 351b are arranged symmetrically with respect to the center line 341. The driving units 351a and 351b are arranged generally in the center of the rotating stage 330 in the V direction.

2.2 Operation

Next, the operation of the gas laser device 100 of the comparative example will be described. Hereinafter, the mirror unit 300 illustrated in FIGS. 5 and 6 will be used for explanation.

Before the gas laser device 100 outputs the pulsed laser beam, the internal spaces of the optical path pipes 68a, 70a, and 161a and the internal spaces of the housings 68 and 151a are filled with the purge gas from a purge gas supply source (not illustrated). A laser gas is supplied to the internal space of the housing 30 from a laser gas supply device (not illustrated).

When the gas laser device 100 outputs the pulsed laser beam, the processor 190 sets a predetermined charging voltage to the charger and turns ON the switch. As a result, the pulse power module generates a pulsed high voltage from the electric energy held in the charger, and a high voltage is applied between the electrode 32a and the electrode 32b. When a high voltage is applied, breakdown occurs between the electrode 32a and the electrode 32b and discharge occurs. When the discharge occurs, the laser medium contained in the laser gas between the electrode 32a and the electrode 32b is brought into an excited state and outputs spontaneous emission light when returning to the ground state. A part of this radiation is ultraviolet light and is transmitted through the window 31b. When the transmitted light passes through the prisms 61, 62, 63, and 64, the width of the transmitted light is enlarged in the traveling direction of the light and is wavelength-dispersed. The light from the prism 63 is reflected by the mirror 310 toward the prism 64, and is guided to the grating 66 through the prism 64. The light is incident on and diffracted by the grating 66 at a predetermined angle, and light of a desired wavelength is reflected by the grating 66 at the same reflection angle as the incident angle. The light reflected by the grating 66 propagates again from the window 31b to the inner space of the housing 30 through the prisms 61, 62, 63, and 64 and the mirror 310. The light propagating to the internal space of the housing 30 is narrowed. With this narrowed light, the laser medium in the excited state undergoes stimulated emission, and the light is amplified. The light passes through the window 31a and travels to the output coupling mirror 70. A part of the light is transmitted through the output coupling mirror 70, and a remaining part of the light is reflected by the output coupling mirror 70, passes through the window 31a, and propagates to the inner space of the housing 30. The light propagated to the inner space of the housing 30 travels to the grating 66 through the window 31b, the prisms 61, 62, 63, and 64, and the mirror 310 as described above. Thus, light of a predetermined wavelength reciprocates between the grating 66 and the output coupling mirror 70. The light is amplified every time the light passes through the discharge space in the internal space of the housing 30, and laser oscillation occurs. Then, a part of the laser beam passes through the output coupling mirror 70 as a pulsed laser beam and travels to the beam splitter 151b. Incidentally, as described above, the windows 31a and 31b are inclined so as to form a Brewster's angle with respect to the traveling direction of the laser beam so as to suppress the reflection of the P-polarized light of the laser beam. In addition, as described above, films are formed on the respective side surfaces of the prisms 61, 62, 63, and 64 so as to suppress the reflection of the P-polarized light of the laser beam traveling from the outside of the respective prisms 61, 62, 63, and 64 to these side surfaces. Therefore, the pulsed laser beam traveling to the beam splitter 151b is narrowed, and the polarization component in the H direction is increased.

A part of the pulsed laser beam traveling to the beam splitter 151b is reflected by the beam splitter 151b. The reflected pulsed laser beam is received by the optical sensor 151c, and the optical sensor 151c measures the pulse energy of the received pulsed laser beam. The optical sensor 151c outputs a signal indicating the pulse energy to be measured to the processor 190. Further, a signal indicating the wavelength of light to be output from the gas laser device 100 is input to the processor 190 from the exposure device 200. The processor 190 controls the prism driving unit and the driving units 351a and 351b on the basis of the signal from the optical sensor 151c and the exposure device 200, and rotates the rotating stages 63a and 330. During the rotation of the rotating stage 330, the driving units 351a and 351b rotate the holding part 320 via the rotating stage 330 so that the mirror 310 rotates about the shaft 340. Specifically, when the driving units 351a and 351b are driven in opposite directions to each other, the rotating stage 330 is pushed and pulled by the driving units 351a and 351b and rotates about the shaft 340 together with the holding part 320. The rotation angle of the rotating stages 63a and 330 is, for example, in an approximate range of ±2.5 degrees. The rotation of the rotating stages 63a and 330 changes the orientations of the prism 63 and the mirror 310. Even when the shaft 340 is a virtual axis without a substance, the driving units 351a and 351b are driven in opposite directions, so that the rotating stage 330 is pushed and pulled by the driving units 351a and 351b and rotate about the shaft together with the holding part 320.

By changing the orientations of the prism 63 and the mirror 310, the wavelength of the light reflected by the grating 66 and returned into the housing 30 of the chamber device CH is adjusted. That is, the processor 190 adjusts the rotational angle of the prism 63 and the mirror 310 on the basis of the signal from the optical sensor 151c and the exposure device 200, and feedback-controls the charging voltage of the charger so that the difference between the pulse energy and the target pulse energy is within an allowable range. When the difference is within the allowable range, the light passes through the beam splitter 151b and the exit window 161 and enters the exposure device 200. The pulsed laser beam is an ArF laser beam which is ultraviolet light having a center wavelength of 193.4 nm.

2.3 Problem

The gas laser device 100 of the present embodiment performs two-wavelength oscillation in which the oscillation wavelength of the pulsed laser beam output from the gas laser device 100 toward the exposure device 200 is repeatedly switched between two wavelengths every one to several pulses. In the two-wavelength oscillation, the two wavelengths are switched by changing the angle of incidence on the grating 66 by adjusting the rotation angle of the mirror 310. By this two-wavelength oscillation, the workpiece is irradiated with two pulsed laser beams having different focal depths. The focal depths of the two pulsed laser beams are shifted between a shallow portion and a deep portion with respect to the workpiece as compared with the case of one-wavelength oscillation in which the focal depth is not changed. By irradiating the two pulsed laser beams to the same portion of the workpiece, for example, a thin and deep uniform hole is formed in the workpiece as compared with the case of the one-wavelength oscillation.

When the gas laser device 100 performs two-wavelength oscillation, the mirror 310 needs to rotate at a high speed in order to repeatedly switch the oscillation wavelength between two wavelengths. Incidentally, in the first overall configuration example of the mirror unit 300 shown in FIGS. 3 and 4, when a stepping motor is used as the driving unit 371, the rotation speed of the mirror 310 rotated by the stepping motor may be slower than the speed obtained by the two-wavelength oscillation. If the rotation speed is slow, the gas laser device 100 may not be able to perform the two-wavelength oscillation. Therefore, in the driving unit 371, a piezo element is used instead of the stepping motor, and the piezo element provides the rotation speed of the mirror 310 required for the two-wavelength oscillation.

Incidentally, when the rotational velocity of the mirror 310 increases, the load applied to the leaf springs 360a and 360b by the rotation of the mirror 310 increases, and the positional deviation occurs in the leaf springs 360a and 360b due to the load, and the fixing force of the leaf springs 360a and 360b may decrease. If the fixing force decreases, the rigidity of the entire mirror unit 300 may decrease. When the rigidity decreases, the responsiveness of the rotation of the mirror 310, that is, the controllability of the rotation of the mirror 310 decreases. Therefore, the mirror unit 300 shown in FIGS. 5 and 6 in which the adhesives 380a, 380b, and 380c are provided instead of the leaf springs 360a and 360b is used.

During bonding, the adhesives 380a, 380b, and 380c pull the mirror 310 toward the rotating stage 330 in the H direction perpendicular to the reflective surface 310a by the respective curing shrinkage. As a result, the tensile force of the adhesives 380a, 380b, and 380c may be applied to the mirror 310 and propagated to the reflective surface 310a via the mirror 310. When the tensile force propagates to the reflective surface 310a, the reflective surface 310a may be distorted. In particular, when the adhesives 380a, 380b, and 380c adhere to the rear surface of the mirror 310 and the surface of the bottom portion of the holding part 320, the mirror 310 is more stable, but the distortion is increased. In order to suppress the distortion, it may be contemplated to reduce the quantity of the adhesives 380a, 380b, and 380c. However, when the quantity of the adhesives 380a, 380b, and 380c is reduced, the respective adhesive forces are reduced. When the adhesive force decreases, the mirror 310 may be detached from the adhesives 380a, 380b, and 380c due to loads applied to the adhesives 380a, 380b, and 380c when the mirror 310 rotates. In addition, when a fastening member is used to fix the holding part 320 and the rotating stage 330, the holding part 320 may be deformed by the fastening force of the fastening member. With the deformation, the holding part 320 may warp around the fastening member. When the holding part 320 is deformed as described above, the stress generated by the deformation may propagate to the adhesives 380a, 380b, and 380c. Further, the stress may propagate from the adhesives 380a, 380b, and 380c to the reflective surface 310a via the mirror 310, and the reflective surface 310a may be distorted. As described above, the distortion of the reflective surface 310a and the detachment of the mirror 310 may cause the gas laser device 100 not to output a pulsed laser beam satisfying the performance required from the exposure device 200, and thus the reliability of the gas laser device 100 may deteriorate.

Therefore, in the following embodiments, the line narrowing module 60 is exemplified in which a decrease in reliability of the gas laser device 100 can be suppressed.

### 3. Description of Line Narrowing Module of First Embodiment

Next, the line narrowing module 60 according to the first embodiment will be described. Configurations similar to those described above are denoted by identical reference signs, and duplicate description thereof is omitted unless otherwise specified.

3.1 Configuration

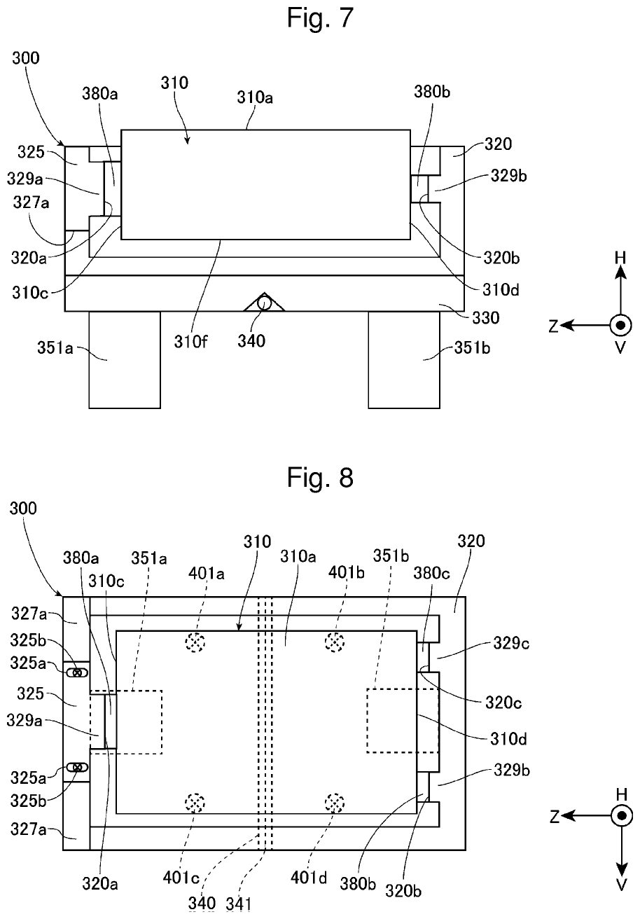

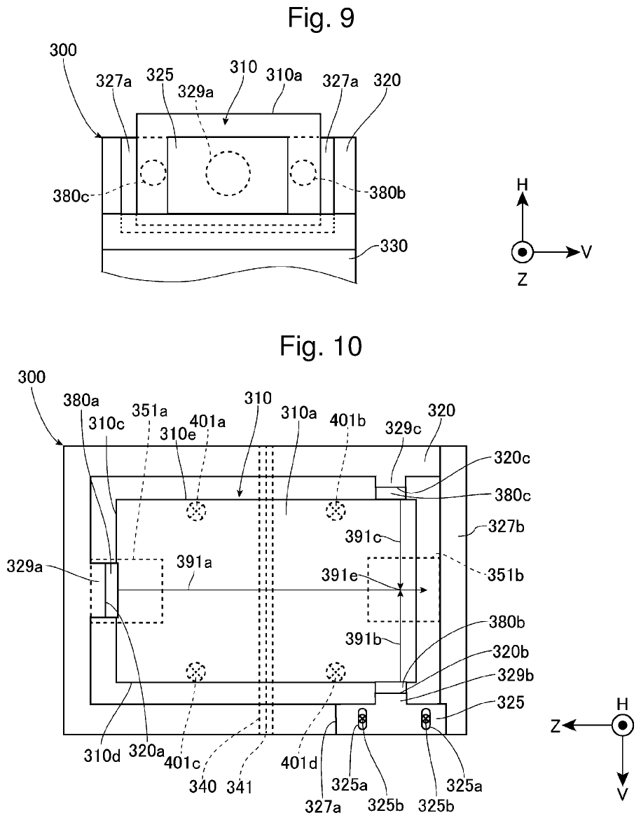

FIG. 7 is a schematic diagram illustrating an overall configuration example of the mirror unit 300 of the present embodiment. FIG. 8 is a front view of the mirror unit 300 shown in FIG. 7. FIG. 9 is a side view of the mirror unit 300 viewed from a plate member 325 side.

The mirror unit 300 of the present embodiment is different from the mirror unit 300 shown in FIGS. 5 and 6 in that the holding part 320 includes a member that can be detachably attached to the holding part 320. Hereinafter, the plate member 325 is used as an example of the member, but a wall member or the like may also be used. Further, the mirror unit 300 is different from the mirror unit 300 shown in FIGS. 5 and 6 in that the adhesive 380a adheres to the side surface of the mirror 310 and the plate member 325 included in the peripheral wall of the holding part 320, and that the adhesives 380b and 380c adhere to the side surface of the mirror 310 and the inner peripheral surface of the peripheral wall of the holding part 320.

The plate member 325 is disposed in the cutout portion 327a provided in the peripheral wall of the holding part 320. The cutout portion 327a is provided in one of the wall portions along the HV plane of the peripheral wall, penetrates the peripheral wall in the Z direction, and is longer than the mirror 310 in the V direction. The plate member 325 is shorter than the cutout portion 327a and the mirror 310 in the V direction. The plate member 325 has a quadrangular prism shape and is made of the same material as the holding part 320. A side surface of the plate member 325 along the HV plane faces one side surface along the HV plane of the mirror 310. The plate member 325 is disposed in the holding part 320 in a state in which the adhesive 380a adheres to a base 329a (described later) of the plate member 325, after the mirror 310 passes through the cutout portion 327a and is disposed inside the peripheral wall. Incidentally, the plate member 325 is a wall to which the adhesive 380a adheres, and the plate member 325 is provided with a pair of through-holes 325a. The through-hole 325a is longer in the Z direction than in the V direction and penetrates the plate member 325 in the H direction. The plate member 325 is fixed to the holding part 320 with an adjustment of the position of the adhesive 380a in the thickness direction by fastening the fastening member 325b, which is a screw, passing through the through-hole 325a and fastening it to the holding part 320. The thickness direction is the Z direction connecting the mirror 310, the adhesive 380a, and the plate member 325 of the holding part 320, and is a direction perpendicular to the shaft 340 when the reflective surface 310a is viewed from the front. The thickness direction is a direction perpendicular to the axis perpendicular to the reflective surface 310a and the center line 341, and is a direction connecting the adhesive surface between the plate member 325 and the adhesive 380a and the adhesive surface between the mirror 310 and the adhesive 380a. The method of fixing the plate member 325 is not limited to the foregoing, and the plate member 325 may be fixed to the holding part 320 by adhesion.

The plate member 325 is provided with the base 329a. Bases 329b and 329c are also provided on the inner peripheral surface of the peripheral wall of the holding part 320. The bases 329b and 329c are provided on the other side of the base 329a with respect to the center line 341.

The holding part 320 includes holding surfaces 320a, 320b, and 320c to which adhesives 380a, 380b, and 380c adhere to hold the mirror 310. The holding surfaces 320a, 320b, and 320c differ from each other. The holding surface 320a is a surface of the base 329a to which the adhesive 380a which is the first adhesive adheres. The holding surface 320b is a surface of the base 329b to which the adhesive 380b which is the second adhesive adheres. The holding surface 320c is a surface of the base 329c to which the adhesive 380c which is the third adhesive adheres. The holding surfaces 320a, 320b, and 320c of the present embodiment intersect the VZ plane along the in-plane direction of the reflective surface 310a and extend along the HV plane. The holding surface 320a is provided on a side opposed to the holding surfaces 320b and 320c with respect to the center line 341. The holding surfaces 320a, 320b, and 320c each have a circular shape, but the shape is not particularly limited. The shaft 340 is a rod-shaped member, but may be a virtual axis without a substance. The shaft 340 includes a line perpendicular to the HZ plane in which the light output from the prism 63 is wavelength-dispersed.

The adhesive 380a adheres to the holding surface 320a and the side surface of the mirror 310 facing the holding surface 320a in the base 329a to bond the mirror 310 to the plate member 325. The adhesive 380b adheres to the holding surface 320b and the side surface of the mirror 310 facing the holding surface 320b in the base 329b to bond the mirror 310 to the holding part 320. Meanwhile, the adhesive 380c adheres to the holding surface 320c of the base 329c and the side surface of the mirror 310 facing the holding surface 320c to bond the mirror 310 to the holding part 320. Accordingly, the adhesives 380b and 380c are positioned on an opposite side of the adhesive 380a with respect to the shaft 340, specifically with respect to the center line 341, when the reflective surface 310a is viewed from the front. The front view indicates that the reflective surface 310a is viewed along the H direction perpendicular to the reflective surface 310a. The center of the mirror 310 of the present embodiment is an intersection of diagonal lines of the reflective surface 310a when the reflective surface 310a is viewed from the front. The side surface of the mirror 310 to which the adhesive 380a adheres is a side surface that is different from the side surface of the mirror 310 to which the adhesives 380b and 380c adhere, and faces the side surface. In the mirror unit 300 of the present embodiment, the side surface of the mirror 310 to which the adhesive 380a adheres is the first adjacent surface 310c adjacent to the reflective surface 310a, and the side surface of the mirror 310 to which the adhesives 380b and 380c adhere is the second adjacent surface 310d adjacent to the reflective surface 310a. The first adjacent surface 310c of the present embodiment faces the second adjacent surface 310d. The adhesive 380b and the base 329b are located in the same HV plane as the adhesive 380c and the base 329c, but misaligned in the V direction. Therefore, the adhesive 380b is provided at a position that is different from the adhesive 380c on the second adjacent surface 310d. Thus, the mirror 310 is held at one location by an adhesive 380a on the left side of the shaft 340 and at two locations by the adhesives 380b and 380c on the right side of the shaft 340.

The adhesives 380a, 380b, and 380c and the bases 329a, 329b, and 329c are positioned closer to the reflective surface 310a than the surface of the bottom portion of the holding part 320 in the H direction perpendicular to the reflective surface 310a. Thus, the mirror 310 is held by the holding part 320 by the adhesives 380a, 380b, and 380c while the rear surface 310f, which is the opposing surface facing the reflective surface 310a, is spaced apart from the surface of the bottom portion of the holding part 320. The center of each of the adhesives 380a, 380b, and 380c and the bases 329a, 329b, and 329c is located at approximately the same height in the H direction perpendicular to the reflective surface 310a. In the Z direction, the adhesives 380a, 380b, and 380c and the bases 329a, 329b, and 329c are generally the same length. The base 329a is provided such that the adhesive 380a adheres generally centrally to the mirror 310 in the V direction. The bases 329b and 329c are provided so that the adhesives 380b and 380c adhere to both ends of the mirror 310 in the V direction.

When viewed along the V direction, the adhesive 380a and the base 329a are located above the driving unit 351a, while the adhesives 380b and 380c and the bases 329b and 329c are located above the driving unit 351b. The upper side is the reflective surface 310a side. Further, when viewed along the H direction, the adhesive 380a and the base 329a are disposed above the driving unit 351a, and the driving unit 351b is disposed between: the adhesive 380b and the base 329b; and the adhesive 380c and the base 329c. The adhesive 380b and the base 329b are provided on an opposite side of the adhesive 380c and the base 329c with respect to the driving unit 351b. In addition, the adhesive 380b and the base 329b, as well as the adhesive 380c and the base 329c are symmetrically provided with respect to the driving unit 351b.

The area of the holding surface 320a in the base 329a is substantially the same as the sum of the area of the holding surface 320b in the base 329b and the area of the holding surface 320c in the base 329c. The area of the holding surface 320a is approximately twice the area of the holding surface 320b and the area of the holding surface 320c, respectively. Each of the adhesives 380a, 380b, and 380c adheres to the entirety of each of the holding surfaces 320a, 320b, and 320c. Therefore, the area of the adhesive surface between the holding surface 320a and the adhesive 380a is substantially the same as the sum of the area of the adhesive surface between the holding surface 320a and the adhesive 380b, and the area of the adhesive surface between the holding surface 320a and the adhesive 380c. Further, the area of the adhesive surface between the holding surface 320a and the adhesive 380a is approximately twice the area of the adhesive surface between the holding surface 320a and the adhesive 380b, and the area of the adhesive surface between the holding surface 320a and the adhesive 380c, respectively. The relationship between the areas of the adhesive surfaces of the holding surfaces 320a, 320b, and 320c and the adhesives 380a, 380b, and 380c has been described above, but the same applies to the relationship between the areas of the adhesive surfaces of the mirror 310 and the adhesives 380a, 380b, and 380c.

The mirror unit 300 further includes fastening members 401a, 401b, 401c, and 401d that fix the rotating stage 330 to the holding part 320. The fastening members 401a, 401b, 401c, and 401d are disposed below the mirror 310 in the bottom portion of the holding part 320, and are therefore indicated by broken lines in FIG. 8. The longitudinal direction of the fastening members 401a, 401b, 401c, and 401d extends in the H direction. The fastening members 401a, 401b, 401c, and 401d are arranged such that they are each located at the apex of the rectangle. The fastening member 401a is disposed on the opposite side of the fastening member 401b with respect to the center line 341, and the fastening member 401c is disposed on the opposite side of the fastening member 401d with respect to the center line 341. Further, the fastening member 401a is disposed on the opposite side of the fastening member 401c with respect to the HZ plane, and the fastening member 401b is disposed on the opposite side of the fastening member 401d with respect to the HZ plane. The number and positions of the fastening members are not limited to the foregoing.

3.2 Function and Effect

In the line narrowing module 60 of the present embodiment, the adhesive 380a, which is the first adhesive, is provided between the first adjacent surface 310c, which is the side surface of the mirror 310, and the holding part 320. The adhesive 380b, which is the second adhesive, is provided between the second adjacent surface 310d, which is the side surface of the mirror 310, and the holding part 320. The adhesive 380a and the adhesive 380b bond the mirror 310 to the holding part 320.

Since the adhesive 380b pulls the mirror 310 toward the holding part 320 in the in-plane direction of the mirror 310 during bonding, the tensile force of the adhesive 380b is applied to the mirror 310 in the in-plane direction. In this case, the adhesive 380b adheres to the rear surface 310f and the surface of the bottom portion of the holding part 320, and the tensile force propagating to the reflective surface 310a may be reduced as compared with the case where the tensile force is applied to the mirror 310 in the H direction perpendicular to the reflective surface 310a. When the tensile force is reduced, distortion of the reflective surface 310a can be suppressed. In addition, since the distortion of the reflective surface 310a is suppressed, it is not necessary to reduce the amount of the adhesives 380a and 380b in order to suppress the distortion of the reflective surface 310a, and it is possible to suppress the decrease in the respective adhesive forces caused by reducing the amount of the adhesives 380a and 380b. When the decrease in the adhesive force is suppressed, the durability against the loads applied to the adhesives 380a and 380b when the mirror 310 is rotated can be increased, and the detachment of the mirror 310 can be suppressed, compared with the case where the decrease in the adhesive force is suppressed. As described above, when the distortion of the reflective surface 310a and the detachment of the mirror 310 are suppressed, the gas laser device 100 can output a pulsed laser beam satisfying the performance required from the exposure device 200. Therefore, a decrease in the reliability of the gas laser device 100 can be suppressed.

In addition, the adhesive 380b is located parallel to the shaft 340 and on the opposite side to the adhesive 380a with respect to the center line 341 passing through the center of the mirror 310 when the reflective surface 310a is viewed from the front. In this case, even if a load is applied to the adhesives 380a and 380b by the rotation of the mirror 310, detachment of the mirror 310 from the adhesives 380a and 380b can be suppressed as compared with a case where the adhesives 380a and 380b are provided on the same side with respect to the center line 341.

Incidentally, when the fastening members 401a, 401b, 401c, and 401d are used to fix the holding part 320 and the rotating stage 330, the holding part 320 may be deformed by the fastening force of the fastening members 401a, 401b, 401c, and 401d. In this deformation, the holding part 320 may warp around the fastening members 401a, 401b, 401c, and 401d. When the adhesives 380a, 380b, and 380c adhere to the rear surface 310f and the holding part 320 as in the comparative example, a stress caused by the deformation may propagate to the adhesives 380a, 380b, and 380c when the holding part 320 is deformed as described above. Further, the stress may propagate from the adhesives 380a, 380b, and 380c to the reflective surface 310a via the mirror 310, and the reflective surface 310a may be distorted. Incidentally, the adhesive 380b of the present embodiment adheres to the holding surface 320b and the side surface of the mirror 310. In this case, even if the holding part 320 is deformed by the fastening force, the stress caused by the deformation may be less likely to propagate through the adhesive 380b and the mirror 310 to the reflective surface 310a than in the case where the adhesive 380b adheres to the rear surface 310f and the holding part 320. When the stress is less likely to propagate, the distortion of the reflective surface 310a can be suppressed. Further, in order to suppress the distortion of the reflective surface 310a due to the fastening force, reduction of fastening members 401a, 401b, 401c, and 401d may be contemplated. However, as described above, since the distortion of the reflective surface 310a due to the fastening force is suppressed by the adhesive 380b, it is not necessary to reduce the fastening members 401a, 401b, 401c, and 401d. In addition, a displacement of the holding part 320 with respect to the rotating stage 330 due to reduction in the fastening members 401a, 401b, 401c, and 401d can be suppressed.

In the line narrowing module 60 of the present embodiment, the first adjacent surface 310c faces the second adjacent surface 310d. Therefore, the adhesives 380a and 380b are provided on both sides of the mirror 310 in the Z direction, and the mirror 310 is held by the holding part 320 from both sides. In this case, as compared with a case where the adhesives 380a and 380b are not provided on both sides of the mirror 310, detachment of the mirror 310 can be suppressed.

Further, the line narrowing module 60 of the present embodiment further includes the adhesive 380c which is the third adhesive that is provided between the second adjacent surface 310d, which is the side surface of the mirror 310 to which the adhesive 380b adheres, and the holding part 320, and bonds the mirror 310 to the holding part 320. In this case, detachment of the mirror 310 can be suppressed as compared with a case where the adhesive 380c is not provided. The adhesive 380c is not necessarily required. If no adhesive 380c is provided, the adhesive 380a is preferably provided symmetrically to the adhesive 380b with respect to the center line 341.

Further, in the line narrowing module 60 of the present embodiment, the adhesives 380a, 380b, and 380c are located at the same height position in the H direction perpendicular to the reflective surface 310a. In this case, detachment of the mirror 310 can be suppressed as compared with a case where the adhesives 380a, 380b, and 380c are not positioned at the same height position in the H direction. Each of the adhesives 380a, 380b, and 380c may not be positioned at the same height position in the H direction.

Further, in the line narrowing module 60 of the present embodiment, when the mirror 310 and the holding part 320 rotate about the shaft 340, loads are applied to the adhesives 380a, 380b, and 380c in the Z direction. The mirror 310 is held at one position by the adhesive 380a on the left side of the shaft 340 in FIG. 8, and at two positions by the adhesives 380b and 380c on the right side of the shaft 340. Incidentally, the area of the adhesive surface between the base 329a and the adhesive 380a is substantially the same as the sum of the area of the adhesive surface between the base 329b and the adhesive 380b and the area of the adhesive surface between the base 329c and the adhesive 380c. In this case, the variation in the loads applied to the adhesive 380a and the adhesives 380b and 380c can be suppressed as compared with a case where the area of the adhesive 380a is not substantially the same as the sum of the areas of the adhesives 380b and 380c. When the variation is suppressed, the variation in the deterioration of the adhesives 380a, 380b, and 380c can be suppressed. Further, the area of the adhesive surface between the base 329a and the adhesive 380a is approximately twice the area of the adhesive surface between the base 329b and the adhesive 380b and the area of the adhesive surface between the base 329c and the adhesive 380c respectively. In this case, as compared with a case where the area of the adhesive 380a is not twice the respective areas on the adhesives 380b and 380c, the variation in the loads applied to the adhesives 380a, 380b, and 380c and the variation in the deterioration of the adhesives 380a, 380b, and 380c can be further suppressed. In the adhesion to the holding part 320, the area on the adhesive 380a side may not be substantially the same as the sum of the areas on the adhesive 380b side and the adhesive 380c side. In addition, the area on the adhesive 380a side may not be approximately twice the area on the adhesive 380b side and the area on the adhesive 380c side.

In the line narrowing module 60 of the present embodiment, the adhesives 380a, 380b, and 380c adhere to the holding surfaces 320a, 320b, and 320c of the bases 329a, 329b, and 329c. The spreading of the adhesive 380a from the holding surface 320a can be suppressed by the edge of the holding surface 320a and the surface tension of the adhesive 380a. Therefore, the area of the adhesive surface between the holding surface 320a and the adhesive 380a may be substantially the same as the area of the holding surface 320a. In addition, by suppressing the above-described spreading, the spreading of the adhesive 380a on the first adjacent surface 310c can be suppressed. Due to the suppression, the area of the adhesive surface between the mirror 310 and the adhesive 380a may be substantially the same as the area of the adhesive surface between the holding surface 320a and the adhesive 380a. Therefore, the area of the adhesive surface of the adhesive 380a between the base 329a side and the mirror 310 side can be adjusted by the holding surface 320a. Although the adhesive 380a has been described above, the same applies to the adhesives 380b and 380c. Thus, the area of the adhesive surface between the mirror 310 and the adhesive 380a is substantially the same as the sum of the area of the adhesive surface between the mirror 310 and the adhesive 380b and the area of the adhesive surface between the mirror 310 and the adhesive 380c. In this case, the variation in the loads applied to the adhesive 380a and the adhesives 380b and 380c can be suppressed as compared with a case where the area on the adhesive 380a side is not substantially the same as the sum of the areas on the adhesive 380b side and the adhesive 380c side. When the variation is suppressed, the variation in the deterioration of the adhesives 380a, 380b, and 380c can be suppressed. The area of the adhesive surface between the mirror 310 and the adhesive 380a is approximately twice the area of the adhesive surface between the mirror 310 and the adhesive 380b and the area of the adhesive surface between the mirror 310 and the adhesive 380c. In this case, variations in the loads applied to the adhesive 380a and the adhesives 380b and 380c can be further suppressed, and variations in the deterioration of the adhesives 380a, 380b, and 380c can be further suppressed. In the bonding between the mirror 310 and the adhesives 380a, 380b, and 380c, the area of the adhesive surface on the adhesive 380a side may not be substantially the same as the sum of the areas of the adhesive surfaces on the adhesive 380b side and the adhesive 380c side. In addition, the area of the adhesive surface on the adhesive 380a side may not be approximately twice the area of the adhesive surface on the adhesive 380b side and the area of the adhesive surface on the adhesive 380c side.

Further, in the line narrowing module 60 of the present embodiment, the plate member 325 is fixed to the holding part 320 by adjusting the position in the Z direction, which is the thickness direction of the adhesive 380a. Accordingly, the plate member 325 can absorb the dimensional tolerance of the mirror 310 and the processing tolerance of the holding part 320 in the Z direction. When the plate member 325 absorbs the dimensional tolerance and the processing tolerance, deformation of the adhesives 380a, 380b, and 380c due to the dimensional tolerance and the processing tolerance can be suppressed. Thus, the misalignment of the mirror 310 can be suppressed. Further, when the plate member 325 absorbs the dimensional tolerance and the processing tolerance, the change in the length of the adhesives 380a, 380b, and 380c in the Z direction due to the dimensional tolerance and the processing tolerance is suppressed, and the change in the adhesive force due to the change in the length can be suppressed.

The plate member 325 of the present embodiment is provided on the adhesive 380a side, but may also be provided on the adhesive 380b side and the adhesive 380c side. Here, one plate member 325 may be provided for the adhesives 380b and 380c, or may be provided for each of the adhesives 380b and 380c. Accordingly, the plate member 325 may be fixed to the holding part 320 by adjusting the position of one of the adhesives 380a, 380b, and 380c in the thickness direction. Further, the spreading of the adhesive 380a to adhere to the plate member 325 and the mirror 310 may also be adjusted by, for example, a frame member (not illustrated) other than the base 329a. Here, the adhesive 380a is provided inside the frame member and hardened, so that the area of the adhesive surface between the holding part 320 and the adhesive 380a is adjusted. If a frame member is used, the base 329a may be omitted. As described above, the method of adjusting the area of the adhesive surface is not particularly limited. Adjusting the area of the adhesive surface has been described with reference to the adhesive 380a, but the same applies to the adhesives 380b and 380c. The base 329a is integral with the plate member 325, but may be separate. The bases 329b and 329c are integral with the peripheral wall, but may be separate. The bases 329a, 329b, and 329c may be provided on the mirror 310. As long as the adhesive surfaces of the adhesives 380a, 380b, and 380c with respect to the mirror 310, the holding part 320, and the plate member 325 are along the HV plane, the positions of the adhesives 380a, 380b, and 380c and the base 329a, 329b, and 329c are not particularly limited. The mirror 310 is only required to have a columnar shape.

In the arrangement positions of the adhesives 380a, 380b, and 380c of the present embodiment, the adhesives 380a, 380b, and 380c are provided on the HV plane, but the present invention is not limited thereto. Other examples of the arrangement positions of the adhesives 380a, 380b, and 380c will be described with reference to first and second modifications below.

FIG. 10 is a front view of a mirror unit 300 in the first modification of the first embodiment. The mirror unit 300 of the present modification is different from the mirror unit 300 of the first embodiment in that the plate member 325 and the cutout portion 327a are provided on one of the wall portions along the HZ plane of the peripheral wall of the holding part 320. The mirror unit 300 of the present modification is different from the mirror unit 300 of the first embodiment in that a third adjacent surface 310e, which is a side surface to which the adhesive 380c of the mirror 310 adheres, is opposed to a second adjacent surface 310d, which is a side surface to which the adhesive 380b adheres. The third adjacent surface 310e is a surface adjacent to the reflective surface 310a. The mirror unit 300 of the present modification is different from the mirror unit 300 of the first embodiment in that the adhesive 380b adheres to the plate member 325 and the mirror 310.

The plate member 325 and the cutout portion 327a are provided on the end side of the mirror 310 on the side opposite to the adhesive 380a in the Z direction. The cutout portion 327a penetrates the circumferential wall in the V direction. In addition, the cutout portion 327a is made shorter than the mirror 310 in the Z direction together with the plate member 325. The plate member 325 is provided with a base 329b, and the holding surface 320b of the base 329b is along the HZ plane. Further, the base 329c is provided on the other side of the base 329b with respect to the mirror 310, and the holding surface 320c of the base 329c is along the HZ plane. Thus, the adhesive 380b is provided on the opposite side of the adhesive 380c with respect to the mirror 310. In addition, the adhesives 380b and 380c are symmetrically provided with respect to the mirror 310. The plate member 325 and the cutout portion 327a may be positioned on the opposite side to the base 329c, and the adhesive 380c may adhere to the base 329b of the plate member 325.

The holding part 320 further includes a cutout portion 327b through which the mirror 310 passes so that the mirror 310 is disposed inside the peripheral wall. The cutout portion 327b is provided in a wall portion of the peripheral wall of the holding part 320 along the HV plane, on a wall portion opposite to the wall portion to which the adhesive 380a adheres with respect to the center line 341. The cutout portion 327b penetrates the circumferential wall in the Z direction and is longer than the mirror 310 in the V direction.

Since the plate member 325 and the cutout portion 327a are not provided at the positions described in the first embodiment, the peripheral wall of the holding part 320 is provided at the positions instead of the plate member 325 and the cutout portion 327a. The peripheral wall is provided with the base 329a, and the base 329a is provided with the holding surface 320a. The adhesive 380a adheres to the holding surface 320a and is positioned on the opposite side to the adhesives 380b and 380c with respect to the center line 341. The adhesive surface between the mirror 310 and the adhesive 380a is along the HV plane, and the respective adhesive surfaces between the mirror 310 and the adhesives 380b and 380c are along the HZ plane. In addition, a first normal line 391a on the adhesive surface between the mirror 310 and the adhesive 380a intersects a second normal line 391b on the adhesive surface between the mirror 310 and the adhesive 380b inside the mirror 310. Further, the first normal line 391a further intersects a third normal line 391c on the adhesive surface between the mirror 310 and the adhesive 380c inside the mirror 310. In addition, the first normal line 391a intersects the third normal line 391c at an intersection 391e between the first normal line 391a and the second normal line 391b. The intersection 391e is located on the opposite side to the adhesive 380a with respect to the center line 341.

In the mirror unit 300 of the present modification, the adhesive 380a pulls the mirror 310 in the Z direction as in the first embodiment. Further, a side surface of the mirror 310 to which the adhesive 380c adheres is opposed to a side surface to which the adhesive 380b adheres, and the adhesives 380b and 380c are provided so as to sandwich the mirror 310, and pulls the mirror 310 in the V direction and shears it in the Z direction. Therefore, the thickness direction of the adhesives 380b and 380c is the V direction, the shearing direction of the adhesives 380b and 380c is the Z direction, and the force combined in the oblique direction between the V direction and the Z direction is applied to the mirror 310. In this case, the rigidity of the entire mirror unit 300 may be increased as compared with a case where the combined force is not applied to the mirror 310.

In the mirror unit 300 of the present modification, the first normal line 391a intersects the second normal line 391b inside the mirror 310. In this case, the rigidity of the entire mirror unit 300 may be increased and the responsiveness of the rotation of the mirror 310 may be improved as compared with a case where the normal lines 391a, 391b do not intersect. Further, in the mirror unit 300 of the present modification, the first normal line 391a intersects the third normal line 391c at the intersection 391e of the first normal line 391a and the second normal line 391b. In this case, the rigidity of the entire mirror unit 300 may be increased and the responsiveness of the rotation of the mirror 310 may be improved as compared with a case where the first normal line 391a does not intersect the third normal line 391c at the intersection 391e.

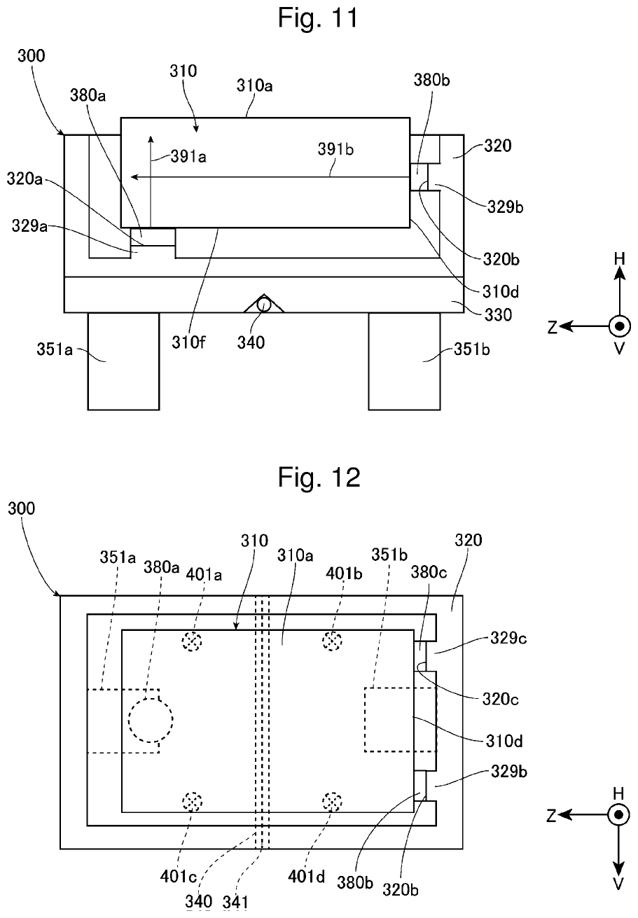

Next, the second modification of the first embodiment will be described. FIG. 11 is a schematic diagram illustrating an overall configuration example of the mirror unit 300 according to the second modification of the first embodiment. FIG. 12 is a front view of the mirror unit 300 shown in FIG. 11. The mirror unit 300 of the present modification is different from the mirror unit 300 of the first embodiment in that the adhesive 380a is provided between the rear surface 310f and the surface of the bottom portion of the holding part 320 facing the rear surface 310f in the same manner as in the comparative example, and the mirror 310 adheres to the holding part 320. The mirror unit 300 of the present modification is different from the mirror unit 300 of the first embodiment in that the plate member 325 and the cutout portion 327a are not provided. In FIG. 12, the adhesive 380a arranged below the mirror 310 is shown by a broken line. The adhesives 380b and 380c are provided in the same manner as in the first embodiment. Therefore, the mirror 310 is held in the rear surface 310f and the second adjacent surface 310d which is the side surface.

In the mirror unit 300 of the present modification, the base 329a is provided on the surface of the bottom portion of the holding part 320. The holding surface 320a of the base 329a is along the VZ plane. Therefore, the adhesive surface of the adhesive 380a with respect to the mirror 310 and the holding surface 320a is along the VZ plane. The base 329a and the adhesive 380a are provided substantially in the center of the mirror 310 in the V direction.

Further, in the mirror unit 300 of the present modification, the adhesive 380a adheres to the rear surface 310f and to the holding surface 320a of the base 329a at the bottom portion of the holding part 320 facing the rear surface 310f. In addition, the adhesives 380b and 380c are provided in the same manner as in the first embodiment, and adhere to the second adjacent surface 310d which is a side surface of the mirror 310 and to the holding surfaces 320b and 320c of the holding part 320 which face the side surface. Thus, the adhesive surface of the adhesive 380a with respect to the mirror 310 and the holding surface 320a is along the VZ plane, and the adhesive surfaces of the adhesives 380b and 380c with respect to the mirror 310 and the holding surface 320a are along the HV plane. Therefore, since the shear direction of the adhesive 380a is perpendicular to the shear direction of the adhesives 380b and 380c, the rigidity of the entire mirror unit 300 may be increased as compared with the cases where the respective shear directions are not perpendicular. Further, by the adhesives 380b and 380c, distortion of the reflective surface 310a can be suppressed as compared with the case where all the adhesives 380a, 380b, and 380c adhere to the rear surface 310f and to the surface of the bottom portion of the holding part 320 as in the comparative example. Further, since it is no longer necessary to absorb the dimensional tolerance of the mirror 310 and the processing tolerance of the holding part 320 by the plate member 325 due to the adhesive 380a, the plate member 325 may be omitted, and processing of the cutout portion 327a in the holding part 320 may be omitted. Even if the mirror 310 is tilted due to the curing shrinkage of the adhesive 380a, the inclination is allowed by the rotation control of the rotating stage 330 by the driving units 351a and 351b.

In the mirror unit 300 of the present modification, as shown in FIG. 11, when viewed from the V direction, the first normal line 391a of the adhesive 380a three-dimensionally intersects the second normal line 391b of the adhesive 380b in the mirror 310. Although not illustrated, the first normal line 391a also intersects the third normal line 391c of the adhesive 380c three-dimensionally in the mirror 310. In such a case, the rigidity of the entire mirror unit 300 may be increased as compared with the case where the respective normal lines of the adhesives 380a, 380b, and 380c do not intersect three-dimensionally. Further, since vibration of the mirror 310 is suppressed in the H direction by the adhesive 380a, the rigidity of the entire mirror unit 300 can be increased as compared with the case where the mirror 310 is fixed only on the HV plane. Therefore, the natural frequency of the mirror 310 may be improved.

### 4. Description of Line Narrowing Module of Second Embodiment

Next, the line narrowing module 60 of the second embodiment is described. Configurations similar to those described above are denoted by identical reference signs, and duplicate description thereof is omitted unless otherwise specified.

4.1 Configuration

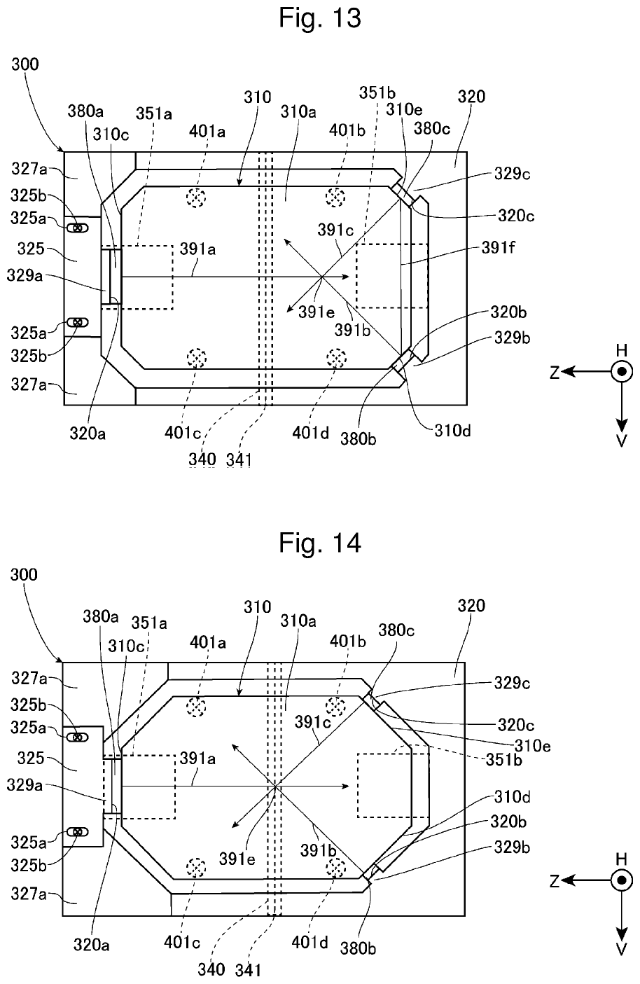

FIG. 13 is a front view of the mirror unit 300 according to the present embodiment. In the mirror unit 300 of the present embodiment, the shape of the mirror 310 is different from the shape of the mirror 310 of the first embodiment.

In the mirror 310 of the present embodiment, the adjacent surfaces 310d, 310e, which are side surfaces to which the adhesives 380b and 380c adhere, are chamfered. The chamfering is, for example, C-chamfering. In this case, the normal lines 391b, 391c are inclined toward the shaft 340 side by the chamfering as compared with the case with no chamfering, the intersection 391e is located between the shaft 340 and the line 391f connecting the adhesives 380b and 380c in the VZ plane along the in-plane direction of the reflective surface 310a. In addition, the intersection 391e is closer to the shaft 340 as compared with the case with no chamfering.

4.2 Function and Effect

In the mirror unit 300 of the present embodiment, the intersection 391e is located between the shaft 340 and the line 391f on the VZ plane. In this case, the rigidity of the entire mirror unit 300 may be increased as compared with a case where the intersection 391e is located on the line 391f, and the responsiveness of the rotation of the mirror 310 may be improved.

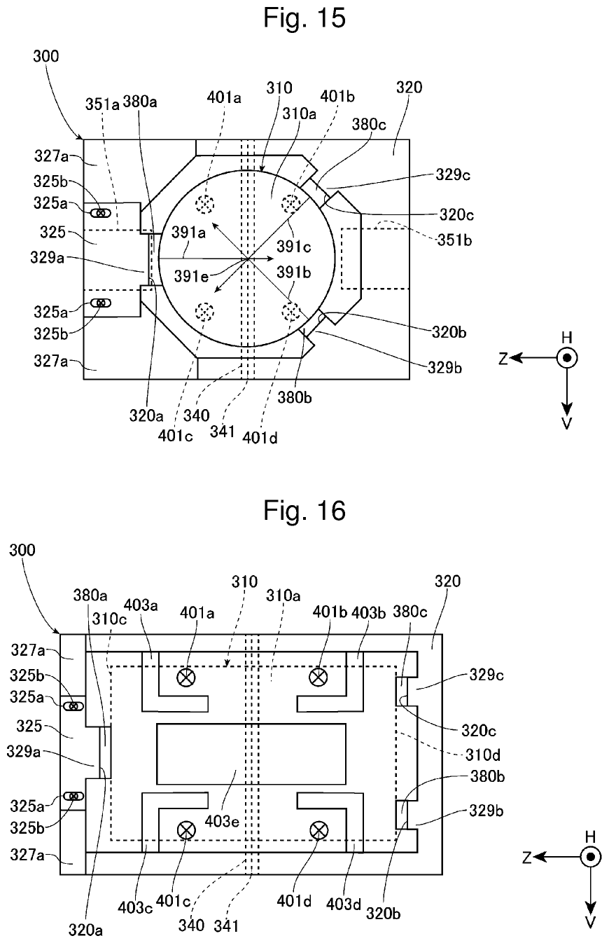

In the line narrowing module 60 of the present embodiment, the intersection 391e is located between the shaft 340 and the line 391f, but the present invention is not limited thereto. FIG. 14 is a front view of the mirror unit 300 in the first modification of the second embodiment. As shown in FIG. 14, the intersection 391e may overlap the shaft 340 when the reflective surface 310a is viewed from the front. In this case, the rigidity of the entire mirror unit 300 may be increased and the responsiveness of the rotation of the mirror 310 may be improved as compared with the case where the intersection 391e is located between the shaft 340 and the line 391f. FIG. 15 is a front view of a mirror unit 300 in the second modification of the second embodiment. The mirror 310 is cylindrical in shape, and the adhesives 380a, 380b, and 380c adhere to the same side surface of mirror 310 at different positions. If the mirror 310 is cylindrical, the intersection 391e can easily overlap the shaft 340 when the reflective surface 310a is viewed from the front, as compared to the case where the mirror 310 is not cylindrical. The intersection 391e may be located between the shaft 340 and the adhesive 380a when the reflective surface 310a is viewed from the front.

### Description of Line Narrowing Module of Third Embodiment

Next, the line narrowing module 60 of the third embodiment is described. Configurations similar to those described above are denoted by identical reference signs, and duplicate description thereof is omitted unless otherwise specified.

Configuration

FIG. 16 is a front view of the mirror unit 300 according to the present embodiment. In FIG. 16, the mirror 310 is indicated by a dotted line, the fastening members 401a, 401b, 401c, and 401d are indicated by solid lines, and the illustration of the driving units 351a and 351b is omitted for ease of viewing. In the mirror unit 300 of the present embodiment, the holding part 320 is different from the holding part 320 of the first embodiment in further including slits 403a, 403b, 403c, 403d, 403e.

Each of the slits 403a, 403b, 403c, 403d has the same size and is L-shaped, and the slit 403e has a rectangular shape elongated in the Z direction. Each of the slits 403a, 403b, 403c, 403d surrounds a part of the fastening members 401a, 401b, 401c, and 401d that fasten the holding part 320 to the rotating stage 330. When the reflective surface 310a is viewed from the front, the slit 403a is provided between the fastening member 401a and the adhesive 380a, and the slit 403b is provided between the fastening member 401b and the adhesive 380c. Further, the slit 403c is provided between the fastening member 401c and the adhesive 380a, and the slit 403d is provided between the fastening member 401d and the adhesive 380b. The slit 403a is located on the opposite side of the slit 403b with respect to the center line 341, and the slit 403c is located on the opposite side of the slit 403d with respect to the center line 341. Further, the slit 403a is located on the opposite side of the slit 403c with respect to the HZ plane, and the slit 403b is located on the opposite side of the slit 403d with respect to the HZ plane. In addition, the slit 403e is located between the slits 403a, 403b and the slits 403c, 403d.

5.2 Function and Effect

In the mirror unit 300 of the present embodiment, stress generated in the holding part 320 in the H direction due to the fastening force of the fastening members 401a, 401b, 401c, and 401d can be reduced by the slits 403a, 403b, 403c, 403d, 403e. When the stress is reduced, deformation of the holding part 320 due to the stress can be suppressed. Further, due to the slits 403a, 403b, 403c, 403d, 403e, the propagation of the stress to the adhesives 380a, 380b, and 380c can be suppressed, and the deformation of the adhesives 380a, 380b, and 380c can be suppressed. Therefore, distortion of the reflective surface 310a can be suppressed. At least one of the slits 403a, 403b, 403c, 403d may be provided.

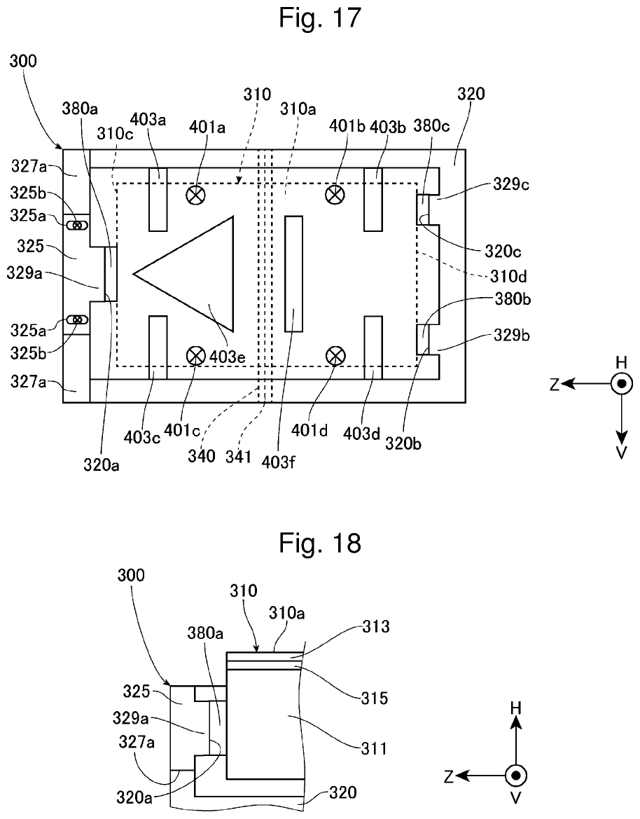

The shapes of the slits 403a, 403b, 403c, 403d, 403e are not limited to the foregoing. FIG. 17 is a front view of the mirror unit 300 according to a modification of the present embodiment. As shown in FIG. 17, each of the slits 403a, 403b, 403c, 403d has the same size and has a rectangular shape elongated in the V direction, and the slit 403e has a triangular shape. An apex among the three apexes of the slit 403e is provided toward the adhesive 380a side, and the remaining two apexes are provided toward the adhesive 380b side and the adhesive 380c side. Further, the holding part 320 is further provided with a rectangular slit 403f elongated in the V direction. The slit 403f is longer than the slit 403a and is provided on the opposite side of the slit 403e with respect to the center line 341. One end of the slit 403f is located between the slit 403a and the slit 403b, and the other end of the slit 403f is located between the slit 403c and the slit 403d. The slit 403f may be connected to the slit 403e.

### 6. Description of Line Narrowing Module of Fourth Embodiment

Next, the line narrowing module 60 of the fourth embodiment is described. Configurations similar to those described above are denoted by identical reference signs, and duplicate description thereof is omitted unless otherwise specified.

6.1 Configuration

FIG. 18 is an enlarged view of a periphery of the adhesive 380a of the fourth embodiment. The mirror 310 mainly includes a substrate 311, a reflective film 313 that reflects a part of the light transmitted through the prism 63 toward the grating 66, and a light shielding film 315 that shields the light transmitted through the reflective film 313 and traveling to the adhesive 380a. The reflective film 313 includes a reflective surface 310a. Although the adhesives 380b and 380c are not illustrated in FIG. 18, the light shielding film 315 also shields light passing through the reflective film 313 and traveling to the adhesives 380b and 380c.

The substrate 311 may be made of, for example, glass, and the adhesives 380a, 380b, and 380c adhere to a side surface of the substrate 311. The light shielding film 315 is made of, for example, aluminum, and the light shielding film 315 is formed on the surface of the substrate 311 by vapor deposition. Since the reflective film 313 is overlaid on the light shielding film 315, the light shielding film 315 is provided between the substrate 311 and the reflective film 313. The reflective film 313 is provided on an opposite side of the substrate 311 with respect to the light shielding film 315. The reflective film 313 is a laminated film in which silicon layers and molybdenum layers are alternately laminated. The outermost layer of the reflective film 313 is a silicon layer. A film other than the silicon layer and the molybdenum layer may be used for the reflective film 313, and a single-layer film of, for example, ruthenium may be provided.

6.2 Function and Effect

In the mirror unit 300 of the present embodiment, since the light shielding film 315 shields the light transmitted through the reflective film 313, the progress of the light toward the adhesives 380a, 380b, and 380c can be suppressed. When the progress of the light is suppressed, deterioration of the adhesives 380a, 380b, and 380c due to the radiation with the light can be suppressed. Further, for example, it may no longer be necessary to widen the area of the adhesive surface between the mirror 310 and each of the adhesives 380a, 380b, and 380c on the assumption of deterioration of the adhesives 380a, 380b, and 380c, and waste of the adhesives 380a, 380b, and 380c due to the widening may be suppressed. The light shielding film 315 is provided between the substrate 311 and the reflective film 313. In this case, the attachment of the light shielding film 315 can be facilitated as compared with the case where the light shielding film 315 surrounds each of the adhesives 380a, 380b, and 380c.

When the light shielding film 315 absorbs light, the light shielding film 315 serves as a heat source, and the adhesives 380a, 380b, and 380c and the reflective film 313 may be deteriorated by the heat, and the reflective film 313 may be distorted by the heat. Therefore, it is preferable that the light shielding film 315 reflects light. The light shielding film 315 may be overlaid on at least a part of the surface of the substrate 311. The light shielding film 315 may shield light traveling to at least one of the adhesives 380a, 380b, and 380c.

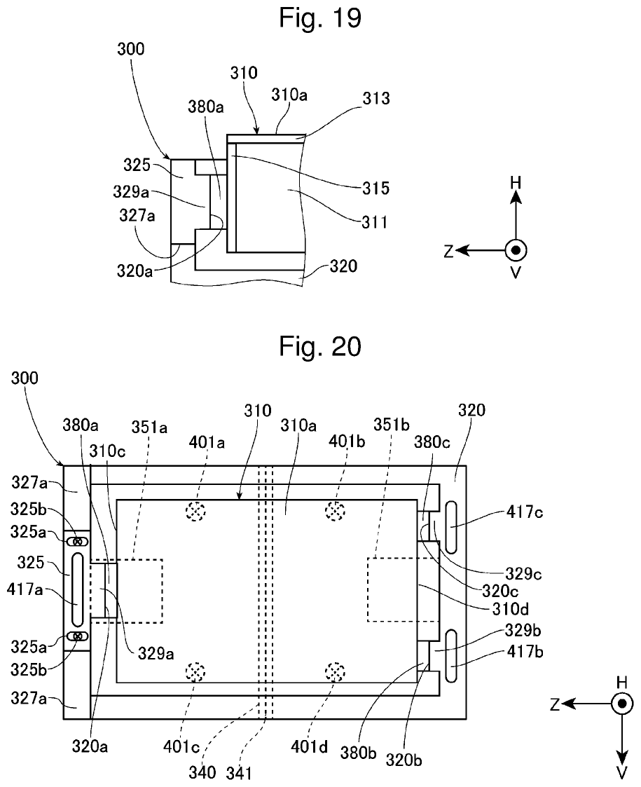

The position of the light shielding film 315 is not limited to the foregoing. FIG. 19 is an enlarged view of a periphery of an adhesive 380a according to a modification of the present embodiment. As illustrated in FIG. 19, the light shielding film 315 may be provided between the substrate 311 and the adhesive 380a. For example, the light shielding film 315 is provided on the entire side surface of the substrate 311 facing the adhesive 380a. The light shielding film 315 may be provided on at least a part of a surface facing the adhesive 380a. Although FIG. 19 has been described with reference to the adhesive 380a, the same applies to the adhesive 380b side and the adhesive 380c side. Further, the light shielding film 315 may be disposed between the substrate 311 and at least one of the adhesive 380a, the adhesive 380b, and the adhesive 380c.

### 7. Description of Line Narrowing Module of Fifth Embodiment

Next, the line narrowing module 60 of the fifth embodiment is described. Configurations similar to those described above are denoted by identical reference signs, and duplicate description thereof is omitted unless otherwise specified.

7.1 Configuration

FIG. 20 is a front view of the mirror unit 300 according to the fifth embodiment. In the mirror unit 300 of the present embodiment, the holding part 320 includes slits 417a, 417b, and 417c adjacent to the adhesives 380a, 380b, and 380c, respectively. The slit 417a is provided in the plate member 325, and the slit 417b and 417c are provided in the peripheral wall of the holding part 320. The longitudinal direction of the slits 417a, 417b, and 417c extends along the shaft 340, i.e., along the V direction. In the V direction, the slit 417a has a length greater than or equal to that of the adhesive 380a. Further, when viewed from the Z direction perpendicular to the longitudinal direction and the H-axis perpendicular to the reflective surface 310a, the slit 417a overlaps at least a part of the adhesive 380a. Although the relationship between the slit 417a and the adhesive 380a has been described above, the same applies to the relationship between the slit 417b and the adhesive 380b and the relationship between the slit 417c and the adhesive 380c. The slits 417a, 417b, and 417c are located at the same height position as the adhesives 380a, 380b, and 380c in the H direction perpendicular to the reflective surface 310a.

7.2 Function and Effect

In the mirror unit 300 of the present embodiment, when the adhesives 380a, 380b, and 380c harden and shrink, the plate member 325 and the holding part 320 are pulled toward the mirror 310 by the tensile force of the adhesives 380a, 380b, and 380c. When the plate member 325 and the holding part 320 are pulled toward the mirror 310, the slits 417a, 417b, and 417c are deformed in the Z direction. Due to the deformation, the deformation of the plate member 325 and the holding part 320 due to the tensile force can be suppressed. In addition, when the mirror 310 is irradiated with the light, the holding part 320 and the mirror 310 may be deformed by the heat of the light. When the holding part 320 and the mirror 310 are to be deformed, the slits 417a, 417b, and 417c are deformed in the Z direction, and the deformation of the plate member 325 and the holding part 320 can be suppressed due to the deformation of the slits 417a, 417b, and 417c. Therefore, the slits 417a, 417b, and 417c absorb the stress in the Z direction caused by the tensile force and the heat, and suppresses deformation of the plate member 325 and the holding part 320. When the deformation of the plate member 325 and the holding part 320 is suppressed as described above, the distortion of the reflective surface 310a can be suppressed.

In the mirror unit 300 of the present embodiment, the slits 417b and 417c may be omitted, or the slit 417a may be omitted. Therefore, the holding part 320 is only required to include a slit that overlaps at least a part of the adhesive among the adhesives 380a, 380b, and 380c that adheres to the side surface of the mirror 310 in the thickness direction and is provided on the wall of the holding part 320 to which the adhesive adheres. The slits 417a, 417b, and 417c may be grooves or through holes.

### 8. Description of Line Narrowing Module of Sixth Embodiment

Next, the line narrowing module 60 of the sixth embodiment is described. Configurations similar to those described above are denoted by identical reference signs, and duplicate description thereof is omitted unless otherwise specified.

8.1 Configuration

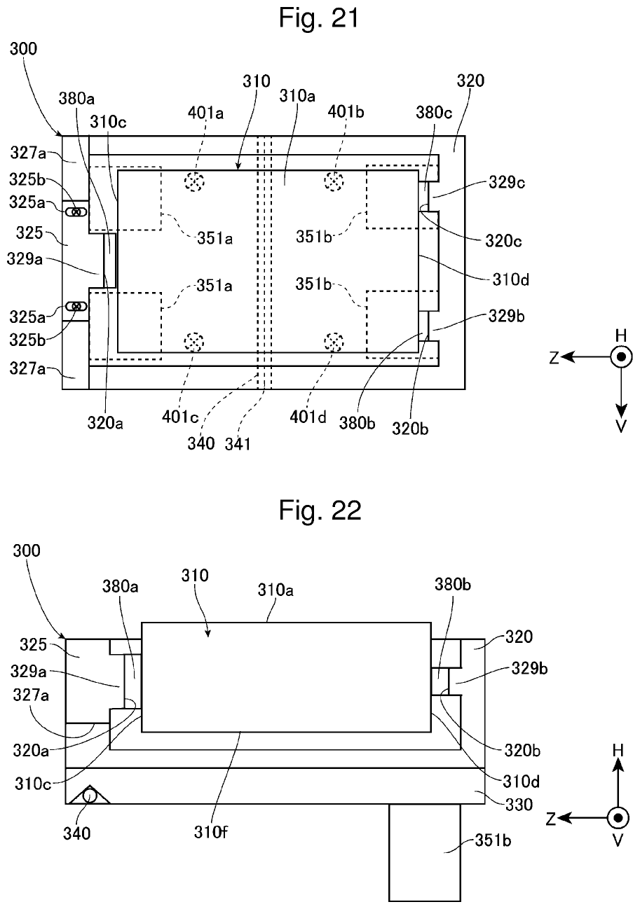

FIG. 21 is a diagram for describing the arrangement of the driving unit in the sixth embodiment. In the mirror unit 300 of the present embodiment, four driving units, specifically a pair of driving units 351a and a pair of driving units 351b are respectively arranged. The pair of driving units 351a is disposed on the opposite side of the pair of driving units 351b with respect to the center line 341. The pair of driving units 351a and the pair of driving units 351b are arranged so as to be located at the apexes of the rectangle. The pair of driving units 351a and the pair of driving units 351b are arranged in parallel at intervals in the V direction which is the axial direction. One of the driving units 351a is disposed on the opposite side of the other of the driving units 351a with respect to the adhesive 380a and the base 329a. One of the driving units 351b is disposed below the adhesive 380b and the base 329b, and the other of the driving units 351b is disposed below the adhesive 380c and the base 329c. Driving of the pair of driving units 351a and driving of the pair of driving units 351b are opposite to each other in the H direction, whereby the pair of driving units 351a and the pair of driving units 351b rotate the mirror 310 about the shaft 340.

8.2 Function and Effect

In the mirror unit 300 of the present embodiment, the pair of driving units 351a and the pair of driving units 351b are respectively arranged. As a result, as compared with the case where only either one of the pair of driving units 351a and the pair of driving unit 351b is disposed, the pitching occurring in the V direction can be reduced, and the rotational property of the mirror 310 can be stabilized. Further, by individually controlling each of the pair of driving units 351a and the pair of driving unit 351b, the pitching can be further reduced. When the pair of driving units 351a or 351b is arranged, the mirror 310 may rotate about the Z axis. However, if two pairs of driving units 351a and 351b are provided, the rotational speed may be suppressed, and stability of the mirror 310 can be improved. The pair of driving units 351a need not be arranged in parallel at an interval in the V direction, which is the axial direction, but may be arranged to be misaligned in the Z direction. Although the pair of driving unit 351a has been described, the same applies to the pair of driving unit 351b. It is preferable that the number of the driving units 351a and 351b is the same, but it may be different.

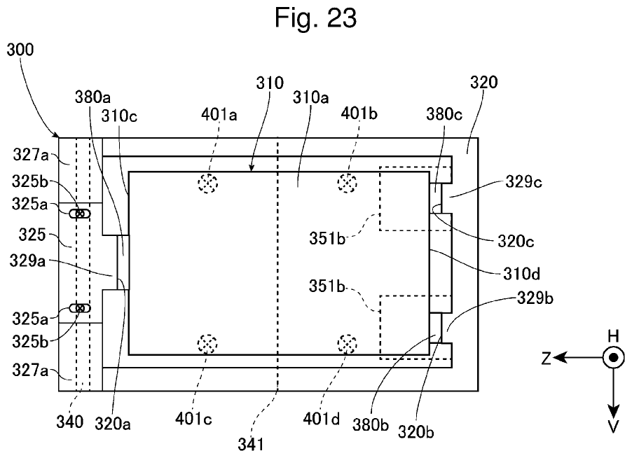

Arrangement of the driving units is not limited to the foregoing. FIG. 22 is a schematic diagram illustrating an overall configuration example of the mirror unit 300 in the modification of the present embodiment. FIG. 23 is a diagram for explaining the arrangement of the driving units in the present modification. In the mirror unit 300 of the present modification, the shaft 340 is provided on the end side of the holding part 320 in the V direction, and is provided below the plate member 325. Further, in the mirror unit 300 of the present modification, the pair of driving units 351a is not provided, and only the pair of driving units 351b is provided. The pair of driving units 351b is arranged at a position misaligned from the center line 341 in the Z direction perpendicular to the shaft 340, and is arranged in parallel at an interval in the V direction which is the axial direction. In the mirror unit 300 of the present modification, the number of components can be reduced and a finer amplitude-width can be realized as compared with the case where the pair of driving units 351a and the pair of driving units 351b are provided. In the present modification, the arrangement positions of the shaft 340 and the pair of driving units 351b may be reversed.

The description above is intended to be illustrative and the present disclosure is not limited thereto. Thus, it would be obvious to those skilled in the art that changes may be made to the embodiments of the present disclosure without departing from the scope of the claims set out below. Further, it would be also obvious to those skilled in the art that embodiments of the present disclosure would be appropriately combined.

Terms used throughout the specification and the claims should be interpreted as “non-limiting” terms unless expressly stated otherwise. For example, terms such as “comprise”, “include”, and “contain” should not be interpreted to be exclusive of other structural elements. For example, terms such as “have”, and “having” should not be interpreted to be exclusive of other structural elements. Further, indefinite articles “a/an” should be interpreted to mean “at least one” or “one or more.” Further, “at least one of A, B, and C” should be interpreted to mean any of A, B, C, A+B, A+C, B+C, and A+B+C. In addition, combinations thereof with other matters than A, B, and C should also be construed as being encompassed.

What is claimed is:

1. A line narrowing module comprising:
a prism;
a mirror including a reflective surface reflecting light transmitted through the prism, a first adjacent surface and a second adjacent surface adjacent to the reflective surface, and an opposing surface opposed to the reflective surface;
a grating that wavelength-disperses the light reflected by the reflective surface;
a holding part that holds the mirror;
a first adhesive provided between the holding part and the first adjacent surface or between the holding part and the opposing surface and bonding the mirror to the holding part;
a second adhesive provided between the holding part and the second adjacent surface and bonding the mirror to the holding part; and
a driving unit configured to rotate the holding part so that the mirror rotates about an axis perpendicular to a plane in which the light is wavelength-dispersed,
the second adhesive being located on an opposite side of the first adhesive with respect to a center line which passes through a center of the mirror in parallel to the axis when the reflective surface is viewed from front.

2. The line narrowing module according to claim 1,
wherein the first adjacent surface is opposed to the second adjacent surface.

3. The line narrowing module according to claim 1,
wherein a first normal line on an adhesive surface between the mirror and the first adhesive that adheres to the first adjacent surface intersects a second normal line on an adhesive surface between the second adhesive and the mirror on an inside of the mirror.

4. The line narrowing module according to claim 3, further comprising a third adhesive located on an opposite side of the first adhesive with respect to the center line when the reflective surface is viewed from the front, the third adhesive being provided between the holding part and a third adjacent surface and bonding the mirror to the holding part, the third adjacent surface being adjacent to the reflective surface of the mirror, wherein
the first normal line intersects a third normal line on an adhesive surface between the third adhesive and the mirror on the inside of the mirror.

5. The line narrowing module according to claim 4, wherein the first normal line intersects the third normal line at an intersection of the first normal line and the second normal line.

6. The line narrowing module according to claim 1, further comprising a third adhesive provided between the holding part and the second adjacent surface and bonding the mirror to the holding part.

7. The line narrowing module according to claim 1, further comprising a third adhesive located on an opposite side of the first adhesive with respect to the center line when the reflective surface is viewed from the front, the third adhesive being provided between the holding part and a third adjacent surface and bonding the mirror to the holding part, the third adjacent surface being adjacent to the reflective surface of the mirror and opposed to the second adjacent surface.

8. The line narrowing module according to claim 1,
wherein the first adhesive adhering to the first adjacent surface and the second adhesive adhering to the second adjacent surface are located at a same height position in a direction perpendicular to the reflective surface.

9. The line narrowing module according to claim 1, further comprising a third adhesive located on an opposite side of the first adhesive with respect to the center line when the reflective surface is viewed from the front, the third adhesive being provided between the holding part and the second adjacent surface and bonding the mirror to the holding part, wherein
area of an adhesive surface between the mirror and the first adhesive is same as a sum of area of an adhesive surface between the mirror and the second adhesive and area of an adhesive surface between the mirror and the third adhesive.

10. The line narrowing module according to claim 1,
wherein
the holding part further includes a member that is attachable and detachable to and from the holding part and to which one of the first adhesive and the second adhesive adheres, and
the member is fixed to the holding part by adjusting a position in a thickness direction of the adhesive orthogonal to the center line and to an axis perpendicular to the reflective surface.

11. The line narrowing module according to claim 1, further comprising:
a rotating stage on which the holding part is placed; and
a fastening member that fastens the holding part to the rotating stage, wherein
the holding part is provided with a slit between the fastening member and at least one of the first adhesive and the second adhesive when the reflective surface is viewed from the front.

12. The line narrowing module according to claim 1,
wherein the mirror further includes a light shielding film that shields the light passing through the reflective surface and traveling to at least one of the first adhesive and the second adhesive.

13. The line narrowing module according to claim 12, wherein
the mirror further includes a reflective film including the reflective surface and a substrate on which the reflective film is provided, and
the light shielding film is provided between the substrate and the reflective film.

14. The line narrowing module according to claim 12, wherein
the mirror further includes a reflective film including the reflective surface and a substrate on which the reflective film is provided, and
the light shielding film is provided at least one of between the substrate and the first adhesive and between the substrate and the second adhesive.

15. The line narrowing module according to claim 1,
wherein
the holding part includes a slit provided in a wall of the holding part to which at least one of the first adhesive adhering to the first adjacent surface and the second adhesive adhering to the second adjacent surface adheres,
a longitudinal direction of the slit extends along the axis, and
when viewed from a direction orthogonal to an axis perpendicular to the reflective surface and to the longitudinal direction of the slit, the slit overlaps at least a part of the adhesive.

16. The line narrowing module according to claim 1,
wherein
four driving units are arranged, a pair of driving units among the four driving units is arranged on an opposite side of the other pair of driving units among the four driving units with respect to the center line, and
each of the pair of driving units and the other pair of driving units is arranged in parallel at an interval in an axial direction.

17. The line narrowing module according to claim 1,
wherein two driving units are arranged, and the driving units are arranged in parallel at respective positions deviated from the center line and at an interval in an axial direction.

18. A gas laser device comprising a line narrowing module, the line narrowing module including:
a prism;
a mirror including a reflective surface reflecting light transmitted through the prism, a first adjacent surface and a second adjacent surface adjacent to the reflective surface, and an opposing surface opposed to the reflective surface;
a grating that wavelength-disperses the light reflected by the reflective surface;
a holding part that holds the mirror;
a first adhesive provided between the holding part and the first adjacent surface or between the holding part and the opposing surface and bonding the mirror to the holding part;
a second adhesive provided between the holding part and the second adjacent surface and bonding the mirror to the holding part; and
a driving unit configured to rotate the holding part so that the mirror rotates about an axis perpendicular to a plane in which the light is wavelength-dispersed,
the second adhesive being located on an opposite side of the first adhesive with respect to a center line which passes through a center of the mirror in parallel to the axis when the reflective surface is viewed from front.

19. A method of manufacturing an electronic device comprising:
generating a laser beam by a gas laser device provided with a line narrowing module, the line narrowing module including a prism,
a mirror including a reflective surface reflecting light transmitted through the prism, a first adjacent surface and a second adjacent surface adjacent to the reflective surface, and an opposing surface opposed to the reflective surface,
a grating that wavelength-disperses the light reflected by the reflective surface,
a holding part that holds the mirror,
a first adhesive provided between the holding part and the first adjacent surface or between the holding part and the opposing surface and bonding the mirror to the holding part,
a second adhesive provided between the holding part and the second adjacent surface and bonding the mirror to the holding part, and
a driving unit configured to rotate the holding part so that the mirror rotates about an axis perpendicular to a plane in which the light is wavelength-dispersed, the second adhesive being located on an opposite side of the first adhesive with respect to a center line which passes through a center of the mirror in parallel to the axis when the reflective surface is viewed from front;
outputting the laser beam to an exposure device; and
exposing a photosensitive substrate to the laser beam in the exposure device to produce the electronic device.
